(19) United States
(12) Patent Application Publication
(10) Pub. No.: US 2015/0280150 A1
(43) Pub. Date: Oct. 1, 2015

(54) BI-, TRI- OR TETRANUCLEAR MIXED METAL COMPLEXES CONTAINING GROUP IB AND IVA ELEMENTS FOR ELECTRONIC DEVICES SUCH AS OLEDS

(71) Applicant: MERCK PATENT GMBH, Darmstadt (DE)

(72) Inventors: Lars Wesemann, Tuebingen (DE); Fritz-Robert Kuechle, Boos (DE); Hermann August Mayer, Tuebingen (DE)

(21) Appl. No.: 14/440,111

(22) PCT Filed: Oct. 15, 2013
(86) PCT No.: PCT/EP2013/003092

§ 371 Date: May 1, 2015

(30) Foreign Application Priority Data
Nov. 3, 2012 (DE) 10 2012 021 650.5

(51) Int. Cl. H01L 51/00; C07F 9/6596; C09K 11/06

(52) U.S. Cl. CPC H01L 51/0094; C09K 11/06; C07F 9/6596; H01L 51/006; H01L 51/0072; H01L 51/0067; H01L 51/0059; H01L 51/0056; H01L 51/0077; H01L 51/0037; H01L 51/0035; C09K 2211/188; C09K 2211/1014; H01L 51/5016

(57) ABSTRACT

The present invention relates to metal complexes which contain elements of group IB and IVA mixed and electronic devices, in particular organic electroluminescent devices, which comprise metal complexes of this type. The compounds claimed are described by formula (1), formula (2) or formula (3), where the following applies to the symbols and indices used: M is on each occurrence, identically or differently, Cu, Ag or Au; E is on each occurrence, identically or differently, Si, Ge or Sn; the other variables are as defined in the claims.

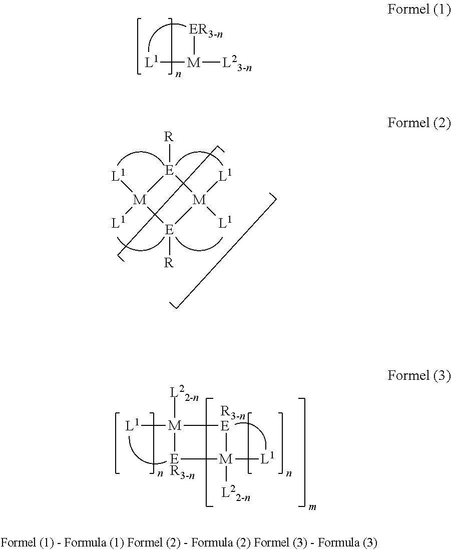

The present invention relates to metal complexes which are suitable for use as emitters in organic electroluminescent devices, and to organic electroluminescent devices which comprise these metal complexes.

The structure of organic electroluminescent devices (OLEDs) in which organic semiconductors are employed as functional materials is described, for example, in U.S. Pat. No. 4,539,507, U.S. Pat. No. 5,151,629, EP 0676461 and WO 98/27136. The emitting materials employed here are frequently organometallic complexes which exhibit phosphorescence instead of fluorescence (M. A. Baldo et al., Appl. Phys. Lett. 1999, 75, 4-6). For quantum-mechanical reasons, an up to four-fold energy and power efficiency is possible using organometallic compounds as phosphorescence emitters. In general, there is still a need for improvement in OLEDs, in particular with respect to efficiency, operating voltage and lifetime. This applies, in particular, to OLEDs which emit in the relatively short-wave region, i.e. green and in particular blue.

In accordance with the prior art, the emitters employed in phosphorescent OLEDs are, in particular, iridium and platinum complexes. Since iridium and platinum are rare metals, it would be desirable, for resource-conserving use, to be able to employ metal complexes based on more widespread metals and to be able to avoid the use of Ir or Pt.

WO 2011/066898 discloses copper complexes having polypodal tri- and tetradentate ligands for use in organic electroluminescent devices.

U.S. Pat. No. 7,462,406 discloses binuclear copper complexes for use in organic electroluminescent devices, where the two copper atoms are bridged by two tridentate amine or phosphine ligands. The central nitrogen or phosphorous atom of the tridentate ligand in each case coordinates to both Cu atoms here, while the two outer nitrogen or phosphorus atoms in each case only coordinate to one of the two Cu atoms.

The object of the present invention is the provision of novel and in particular improved metal complexes which are suitable as emitters for use in OLEDs in order to make it possible for the person skilled in the art to have a greater possible choice of materials for the production of OLEDs. Improvements can relate, for example, to efficiency, lifetime, operating voltage and/or emission colour. Furthermore, it is also the object of the present invention to provide metal complexes based on metals other than iridium or platinum which are suitable for use in OLEDs and result in advantageous properties therein.

Surprisingly, it has been found that certain metal chelate complexes described in greater detail below achieve this object and result in good electroluminescence properties of the organic electroluminescent device. These metal complexes contain, as characterising feature, at least one chelating ligand which is coordinated to the metal atom via a negatively charged Si, Ge or Sn atom and a further coordinating group. These metal complexes may be mononuclear complexes or bi-, tri- or tetranuclear complexes. The present invention relates to these metal complexes and to organic electroluminescent devices which comprise these complexes.

The invention thus relates to a compound of the formula (1), formula (2) or formula (3),

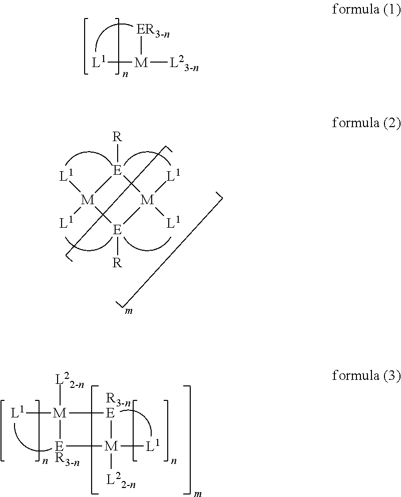

where the following applies to the symbols and indices used:
M is on each occurrence, identically or differently, Cu, Ag or Au;
E is on each occurrence, identically or differently, Si, Ge or Sn;
L¹ is on each occurrence, identically or differently, a coordinating group which is covalently bonded to E via a single bond or a bridging group; furthermore, two coordinating groups L¹ which are bonded to the same metal atom may be linked to one another via a single bond or a bridging unit;
L² is on each occurrence, identically or differently, a monodentate ligand which is coordinated to M, where, in addition, two monodentate ligands L² which are coordinated to the same metal may together form a bidentate ligand; furthermore, L² may also be linked to L¹ via a single bond or a bridging unit, where L² in this case does not represent an independent ligand, but instead a coordinating group;
R is on each occurrence, identically or differently, H, D, F, Cl, Br, I, N(R¹)₂, P(R¹)₂, CN, NO₂, OH, COOH, C(═O)N(R¹)₂, Si(R¹)₃, B(OR¹)₂, C(═O)R¹, P(═O)(R¹)₂, S(═O)R¹, S(═O)₂R¹, OSO₂R¹, a straight-chain alkyl, alkoxy or thioalkoxy group having 1 to 20C atoms or an alkenyl or alkynyl group having 2 to 20C atoms or a branched or cyclic alkyl, alkoxy or thioalkoxy group having 3 to 20C atoms, each of which may be substituted by one or more radicals R¹, where one or more non-adjacent CH₂ groups may be replaced by R¹C═CR¹, C≡C, Si(R¹)₂, C═O, NR¹, O, S or CONR¹ and where one or more H atoms may be replaced by D, F, Cl, Br, I or CN, or an aromatic or hetero-aromatic ring system having 5 to 60 aromatic ring atoms, which may in each case be substituted by one or more radicals R¹, or an aryloxy or heteroaryloxy group having 5 to 40 aromatic ring atoms, which may be substituted by one or more radicals R¹, or an aralkyl or heteroaralkyl group having 5 to 40 aromatic ring atoms, which may be substituted by one or more radicals R¹, or a diarylamino group, diheteroarylamino group or arylheteroarylamino group having 10 to 40 aromatic ring atoms, which may be substituted by one or more radicals R¹; two adjacent radicals R may also form a mono- or polycyclic, aromatic or aliphatic ring system with one another here;
R¹ is on each occurrence, identically or differently, H, D, F, Cl, Br, I, N(R²)₂, P(R²)₂, CN, NO₂, Si(R²)₃, B(OR²)₂, C(═O)R², P(═O)(R²)₂, S(═O)R², S(═O)₂R², OSO₂R², a straight-chain alkyl, alkoxy or thioalkoxy group having 1 to 20C atoms or an alkenyl or alkynyl group having 2 to 20C atoms or a branched or cyclic alkyl, alkoxy or thioalkoxy group having 3 to 20C atoms, each of which may be substituted by one or more radicals R², where one or more non-adjacent CH₂ groups may be replaced by R²C═CR², C≡C, Si(R²)₂, C═O, NR², O, S or CONR² and where one or more H atoms may be replaced by D, F, Cl, Br, I, CN or NO₂, or an aromatic or heteroaromatic ring system having 5 to 60 aromatic ring atoms, which may in each case be substituted by one or more radicals R², or an aryloxy or heteroaryloxy group having 5 to 40 aromatic ring atoms, which may be substituted by one or more radicals R², or an aralkyl or heteroaralkyl group having 5 to 40 aromatic ring atoms, which may be substituted by one or more radicals R², or a diarylamino group, diheteroarylamino group or arylheteroarylamino group having 10 to 40 aromatic ring atoms, which may be substituted by one or more radicals R²; two or more adjacent radicals R² may form a mono- or polycyclic, aromatic or aliphatic ring system with one another here;
R² is on each occurrence, identically or differently, H, D, F or an aliphatic, aromatic and/or heteroaromatic hydrocarbon radical having 1 to 20C atoms, in which, in addition, one or more H atoms may be replaced by F; two or more substituents R² may also form a mono- or polycyclic, aromatic or aliphatic ring system with one another here;
n is 1, 2 or 3 in formula (1) or is 1 or 2 in formula (3);
m is 1, 2 or 3.

The curved line between L¹ and E here indicates either a single bond by means of L¹ is bonded to E, or a bridging, i.e. divalent unit by means of which L¹ is bonded to E.

In compounds of the formulae (2) and (3), the atom E is simultaneously bonded to two metal atoms M and is thus pentacoordinated.

If m in formula (2) or (3) is equal to two, the atoms M and E form a six-membered ring, and the complex is trinuclear. If m in formula (2) or (3) is equal to three, the atoms M and E form an eight-membered ring, and the complex is tetranuclear.

An aryl group in the sense of this invention contains 6 to 40C atoms; a heteroaryl group in the sense of this invention contains 2 to 40C atoms and at least one heteroatom, with the proviso that the sum of C atoms and heteroatoms is at least 5. The heteroatoms are preferably selected from N, O and/or S. An aryl group or heteroaryl group here is taken to mean either a simple aromatic ring, i.e. benzene, or a simple heteroaromatic ring, for example pyridine, pyrimidine, thiophene, etc., or a condensed aryl or heteroaryl group, for example naphthalene, anthracene, phenanthrene, quinoline, isoquinoline, etc.

An aromatic ring system in the sense of this invention contains 6 to 60C atoms in the ring system. A heteroaromatic ring system in the sense of this invention contains 1 to 60C atoms and at least one heteroatom in the ring system, with the proviso that the sum of C atoms and heteroatoms is at least 5. The heteroatoms are preferably selected from N, O and/or S. An aromatic or heteroaromatic ring system in the sense of this invention is intended to be taken to mean a system which does not necessarily contain only aryl or heteroaryl groups, but instead in which, in addition, a plurality of aryl or heteroaryl groups may be interrupted by a non-aromatic unit (preferably less than 10% of the atoms other than H), such as, for example, a C, N or O atom or a carbonyl group. Thus, for example, systems such as 9,9′-spirobifluorene, 9,9-diarylfluorene, triarylamine, diaryl ether, stilbene, etc., are also intended to be taken to be aromatic ring systems in the sense of this invention, as are systems in which two or more aryl groups are interrupted, for example, by a linear or cyclic alkyl group or by a silyl group. Furthermore, systems in which two or more aryl or heteroaryl groups are bonded directly to one another, such as, for example, biphenyl or terphenyl, are likewise intended to be taken to be an aromatic or heteroaromatic ring system.

A cyclic alkyl, alkoxy or thioalkoxy group in the sense of this invention is taken to mean a monocyclic, bicyclic or polycyclic group.

For the purposes of the present invention, a C₁- to C₄₀-alkyl group, in which, in addition, individual H atoms or CH₂ groups may be substituted by the above-mentioned groups, is taken to mean, for example, the radicals methyl, ethyl, n-propyl, i-propyl, cyclopropyl, n-butyl, i-butyl, s-butyl, t-butyl, cyclobutyl, 2-methylbutyl, n-pentyl, s-pentyl, tert-pentyl, 2-pentyl, neopentyl, cyclopentyl, n-hexyl, s-hexyl, tert-hexyl, 2-hexyl, 3-hexyl, neohexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2.2.2]octyl, 2-bicyclo[2.2.2]octyl, 2-(2,6-dimethyl)octyl, 3-(3,7-dimethyl)octyl, adamantyl, trifluoromethyl, pentafluoroethyl or 2,2,2-trifluoroethyl. An alkenyl group is taken to mean, for example, ethenyl, propenyl, butenyl, pentenyl, cyclopentenyl, hexenyl, cyclohexenyl, heptenyl, cycloheptenyl, octenyl, cyclooctenyl or cyclooctadienyl. An alkynyl group is taken to mean, for example, ethynyl, propynyl, butynyl, pentynyl, hexynyl, heptynyl or octynyl. A C₁- to C₄₀-alkoxy group is taken to mean, for example, methoxy, trifluoromethoxy, ethoxy, n-propoxy, i-propoxy, n-butoxy, i-butoxy, s-butoxy, t-butoxy or 2-methylbutoxy.

An aromatic or heteroaromatic ring system having 5-60 aromatic ring atoms, which may also in each case be substituted by the radicals R mentioned above and which may be linked to the aromatic or heteroaromatic ring system via any desired positions, is taken to mean, for example, groups derived from benzene, naphthalene, anthracene, benzanthracene, phenanthrene, benzophenanthrene, pyrene, chrysene, perylene, fluoranthene, benzofluoranthene, naphthacene, pentacene, benzopyrene, biphenyl, biphenylene, terphenyl, terphenylene, fluorene, spirobifluorene, dihydrophenanthrene, dihydropyrene, tetrahydropyrene, cis- or trans-indenofluorene, cis- or trans-monobenzoindenofluorene, cis- or trans-dibenzoindenofluorene, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, indolocarbazole, indenocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubin, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

The metal M is preferably in oxidation state +I. It is thus preferably, identically or differently on each occurrence, Cu(I), Ag(I) or Au(I). These are generally preferably tetracoordinated or at least also known as tetracoordinated metals. In accordance with the invention, the ligand is bonded to the metal via a negatively charged group E. Preference is given, identically or differently on each occurrence, to Cu(I) or Ag(I), in particular Cu(I).

In a preferred embodiment of the invention, the compound of the formula (1) or (2) or (3) is overall electrically neutral. L¹ and L² are therefore preferably groups which coordinate in a neutral manner. If L¹ and/or L² are anionic, the complex also contains one or more cationic counterions. These are preferably selected from the group consisting of alkali metal ions, in particular Li, Na or K, tetraalkylammonium ions and tetraalkylphosphonium ions, where the alkyl groups each have 1 to 10C atoms.

In a preferred embodiment of the invention, E stands, identically or differently on each occurrence, for Si or Ge, in particular for Si.

In a further preferred embodiment of the invention, the index m in compounds of the formula (2) and (3) is equal to 1 or 2, particularly preferably equal to 1.

In a further preferred embodiment of the invention, all metals M in compounds of the formula (2) and (3) are selected identically, in particular equal to Cu.

In still a further preferred embodiment of the invention, all elements E in the compounds of the formula (2) and (3) are selected identically, in particular equal to Si.

In a particularly preferred embodiment of the invention, M in the compounds of the formulae (1), (2) and (3) stands on each occurrence, identically, for Cu(I) or Ag(I), and E stands on each occurrence, identically, for Si or Ge. In a very particularly preferred embodiment of the invention, M stands for Cu(I) and E stands for Si in the compounds of the formulae (1), (2) and (3). This also preferably applies to the other embodiments of the invention indicated below.

In a preferred embodiment of the invention, the compounds of the formula (1) are selected from the structures of the following formulae (1a), (1b), (1c), (1d) or (1e),

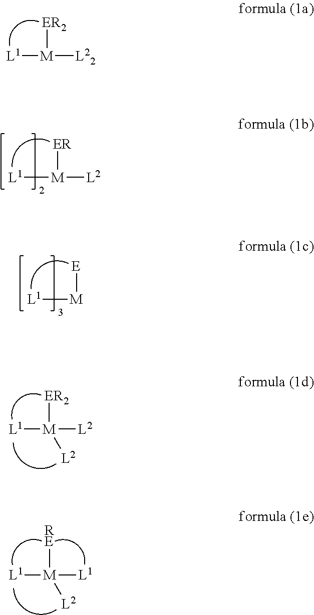

where the symbols used have the meanings given above. Preference is given to the compounds of the formula (1c).

In a further preferred embodiment of the invention, the compounds of the formula (2) are selected from the structures of the following formulae (2a), (2b) or (2c),

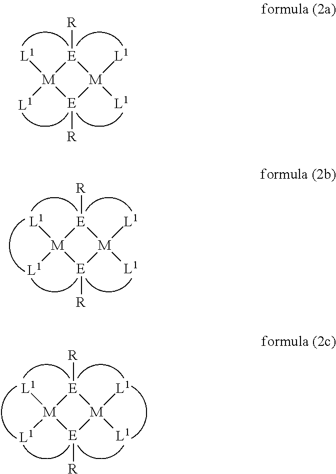

where the symbols used have the meanings given above and the coordinating groups L¹ in formula (2a) and (2b) are not bridged to one another if no bridging is drawn in. Preference is given to the compounds of the formula (2a).

In a further preferred embodiment of the invention, the compounds of the formula (3) are selected from the structures of the following formulae (3a), (3b) or (3c),

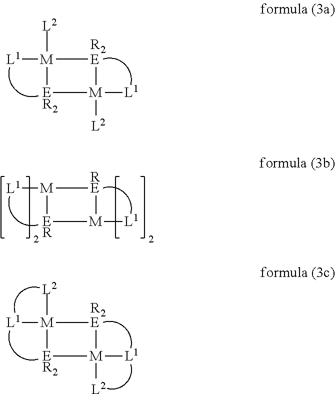

where the symbols used have the meanings given above.

In a further preferred embodiment of the invention, the ring formed by M, E and L¹ is a four-membered ring, five-membered ring, six-membered ring, seven-membered ring or eight-membered ring, in particular a five-membered ring or six-membered ring. In compounds of the formula (1), the ring formed by M, E and L¹ is preferably a six-membered ring, seven-membered ring or eight-membered ring, in particular for n=2 or 3. If the ring formed by M, E and L¹ is a five-membered ring, polycyclic compounds of the formula (2) or (3) are preferably formed, depending on the precise structure of the ligand. It is explained diagrammatically below what is understood under the formation of a five-membered ring or six-membered ring or seven-membered ring or eight-membered ring.

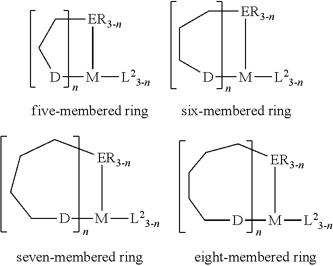

D here stands for the coordinating atom of the coordinating group L¹. Two bridging atoms are present between the coordinating atom D and the group E for the formation of a five-membered ring, three bridging atoms are present for the formation of a six-membered ring, four bridging atoms are present for the formation of a seven-membered ring and five bridging atoms are present for the formation of an eight-membered ring. The bridging units between D and E here are drawn in merely by way of example as carbon atoms. Any desired other groups which are able to link D and E to one another are equally possible, as explained in greater detail, for example, below. Furthermore, D may also be part of a heteroaryl group.

In a preferred embodiment of the invention, the coordinating atom of the coordinating group L¹ is selected, identically or differently on each occurrence, preferably identically, from the group consisting of phosphorus, nitrogen or sulfur, particularly preferably phosphorus and nitrogen.

Preferred coordinating groups L¹ are selected, identically or differently on each occurrence, preferably identically, from the group consisting of PR₂, NR₂, nitrogen-containing heteroaryl groups, which are coordinated to M via a neutral nitrogen atom, sulfur-containing heteroaryl groups, which are coordinated to M via the sulfur atom, in particular thiophene, benzothiophene and dibenzothiophene, Sr and —P═NR, where this group is coordinated to M via N. R here has the meanings given above. Furthermore, the nitrogen-containing or sulfur-containing heteroaryl groups may be substituted by one or more radicals R.

Particularly preferred coordinating groups L¹ are, identical or differently on each occurrence, preferably identically, PR₂ and nitrogen-containing heteroaryl groups, which are coordinated to M via a neutral nitrogen atom, in particular pyridine, quinoline or phenanthridine, each of which may be substituted by one or more radicals R.

The radical R which is bonded to a phosphorus atom, a nitrogen atom or a sulfur atom of the coordinating group L¹ is preferably selected, identically or differently on each occurrence, in particular identically, from the group consisting of a straight-chain alkyl group having 1 to 10C atoms or a branched or cyclic alkyl group having 3 to 10C atoms, each of which may be substituted by one or more radicals R¹, where one or more non-adjacent CH₂ groups may be replaced by R¹C═CR¹ or O and where one or more H atoms may be replaced by D or F, or an aromatic or heteroaromatic ring system having 5 to 24 aromatic ring atoms, which may in each case be substituted by one or more radicals R¹, or an aralkyl or heteroaralkyl group having 5 to 40 aromatic ring atoms, which may be substituted by one or more radicals R¹; two adjacent radicals R which are bonded to the same phosphorus or nitrogen atom may also form a mono- or polycyclic, aromatic or aliphatic ring system with one another here. The radical R which is bonded to a phosphorus atom, a nitrogen atom or a sulfur atom of the coordinating group L¹ is particularly preferably selected, identically or differently on each occurrence, from the group consisting of a straight-chain alkyl group having 1 to 4C atoms or a branched or cyclic alkyl group having 3 or 4C atoms, where one or more H atoms may be replaced by F, or an aromatic or heteroaromatic ring system having 5 to 12 aromatic ring atoms, which may in each case be substituted by one or more radicals R¹.

Furthermore, the radical R which is bonded to a phosphorus atom of the coordinating group L¹ may also be, identically or differently on each occurrence, a straight-chain alkoxy group having 1 to 10C atoms, particularly preferably having 1 to 4C atoms, which may in each case be substituted by one or more radicals R¹, or an aryloxy or heteroaryloxy group having 5 to 24 aromatic ring atoms, which may be substituted by one or more radicals R¹.

If the coordinating group L¹ stands for PR₂ or NR₂, this group is preferably bonded to the atom E, i.e. to the Si, Ge or Sn, via a bridging group in such a way that two, three, four or five bridging atoms are located between the phosphorus or nitrogen atom and the atom E. On coordination to M, a five-membered ring, six-membered ring, seven-membered ring or eight-membered ring thus forms. The bridging unit between the phosphorus or nitrogen atom and E, which is symbolised by the curved line in formula (1), (2) and (3) and the preferred embodiments, is preferably selected from the group consisting of alkylene groups having 2 to 5C atoms, preferably 2 or 3C atoms, which may be substituted by one or more radicals R¹ and in which one or more non-adjacent C atoms may also be replaced by —CR¹═CR¹— or O, or from an aromatic or heteroaromatic ring system having 5 to 18 aromatic ring atoms, which may be substituted by one or more radicals R¹, or a combination of one or two alkylene groups, which may be substituted by one or more radicals R¹ and in which one or more non-adjacent C atoms may also be replaced by —CR¹═CR¹— or O, and an aromatic or heteroaromatic ring system, which are in each case defined as above.

Preferred bridging units for the formation of a five-membered ring if L¹ stands for PR₂ or NR₂ are selected from the structures of the following formulae (4) to (8),

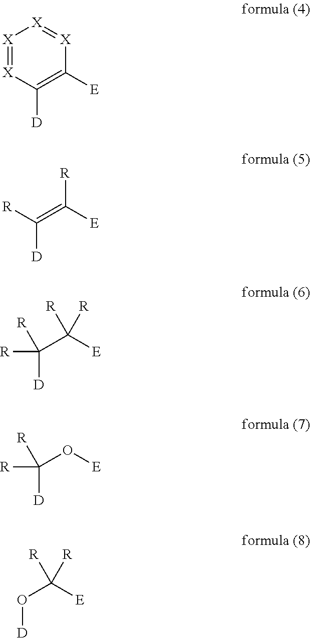

where the symbols used have the meanings given above. In each case, the group E and the coordinating atom D of the coordinating group L¹ are also drawn in here in these structures in order to clarify how this group is bonded. Furthermore, X stands, identically or differently on each occurrence, for CR or N, with the proviso that a maximum of three groups X stand for N and the remaining groups X stand for CR. In a preferred embodiment of the invention, a maximum of two groups X stand for N, particularly preferably a maximum of one group X stands for N, and the other groups X stand for CR. Very particularly preferably, all groups X stand for CR.

The groups of the formulae (4) to (8) are also suitable for the formation of a six-membered ring if the coordinating group L¹ stands for —P═NR.

Preferred bridging units for the formation of a six-membered ring if L¹ stands for PR₂ or NR₂ are selected from the structures of the following formulae (9) to (14),

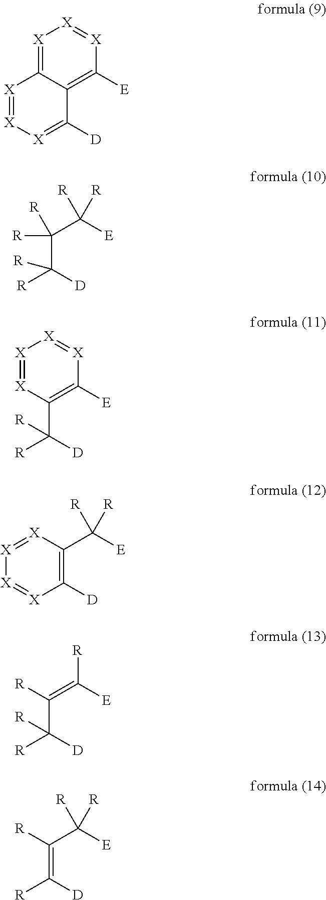

where the symbols used have the meanings given above. In each case, the group E and the coordinating atom D of the coordinating group L¹ are also drawn in here in these structures.

Preferred bridging units for the formation of a seven-membered ring if L¹ stands for PR₂ or NR₂ are selected from the structures of the following formulae (15) to (21),

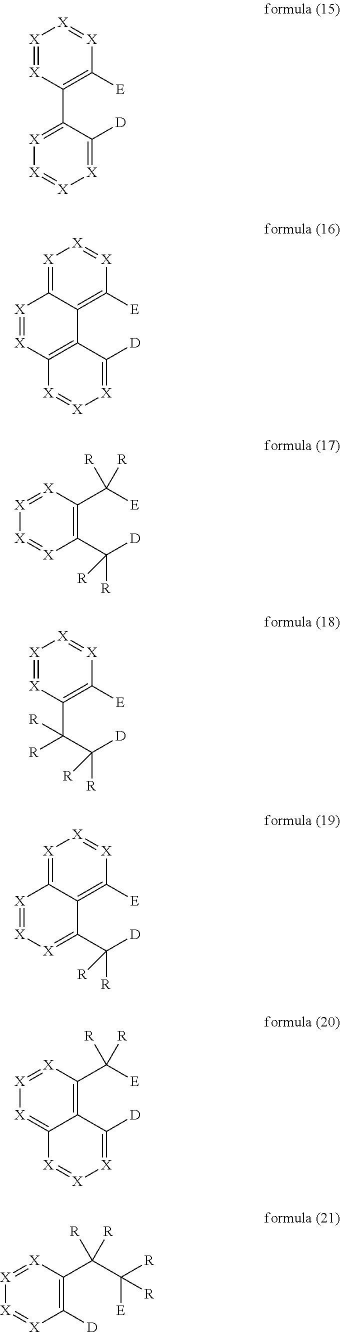

where the symbols used have the meanings given above. In each case, the group E and the coordinating atom D of the coordinating group L¹ are also drawn in here in these structures.

Preferred bridging units for the formation of an eight-membered ring if L¹ stands for PR₂ or NR₂ are selected from the structures of the following formula (22) or (23),

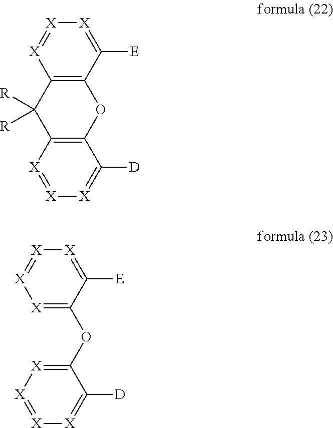

where the symbols used have the meanings given above. In each case, the group E and the coordinating atom D of the coordinating group L¹ are also drawn in here in these structures.

If the coordinating group L¹ is a nitrogen-containing heteroaryl group, this group, together with the bridging group by means of which the heteroaryl group is bonded to E, is preferably selected from the structures of the following formulae (24) to (29),

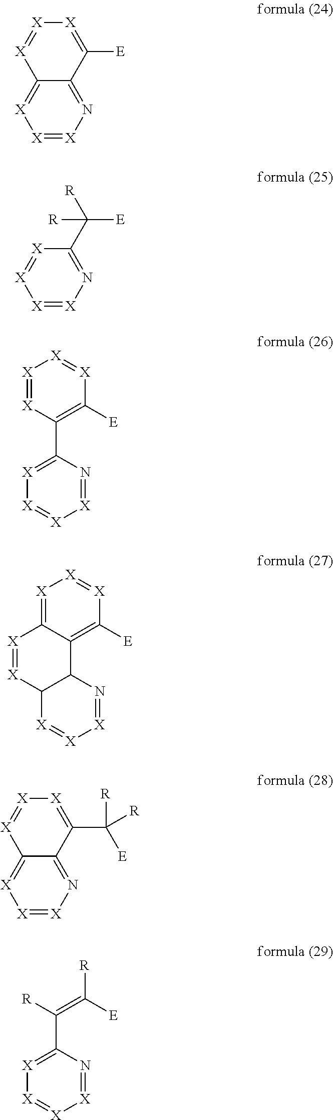

where the symbols used have the meanings given above. In each case, the group E is also drawn in here in these structures. The nitrogen atom of the heteroaromatic group is coordinated to the metal M here.

If the coordinating group L¹ is a sulfur-containing heteroaryl group, this group, together with the bridging group by means of which the heteroaryl group is bonded to E, is preferably selected from the structures of the following formulae (30) to (34),

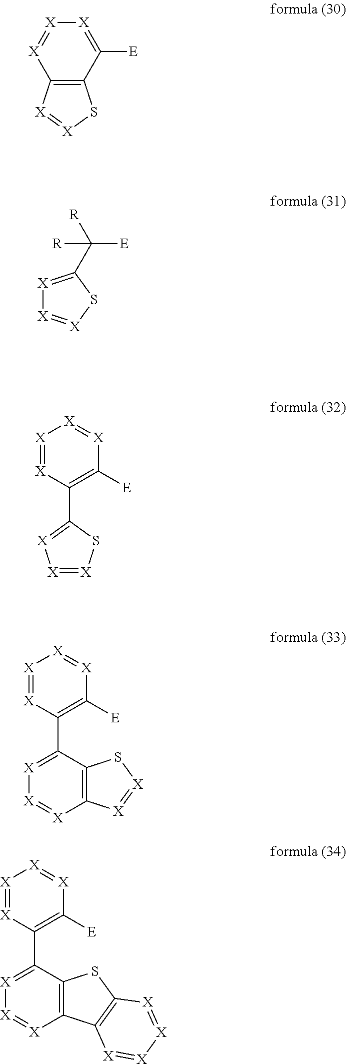

where the symbols used have the meanings given above. In each case, the group E is also drawn in here in these structures. The nitrogen atom of the heteroaromatic group is coordinated to the metal M here.

The structures of the formulae (24), (25), (30) and (31) form a five-membered ring with the metal M here, structures (26) to (29) and (32) form a six-membered ring with the metal M and structures (33) and (34) form a seven-membered ring with the metal M.

In a preferred embodiment of the invention, the substituents R which are bonded to E are selected on each occurrence, identically or differently, from the group consisting of F, a straight-chain alkyl or alkoxy group having 1 to 10C atoms or an alkenyl group having 2 to 10C atoms or a branched or cyclic alkyl or alkoxy group having 3 to 10C atoms, each of which may be substituted by one or more radicals R¹, or a aromatic or heteroaromatic ring system having 5 to 30 aromatic ring atoms, which may in each case be substituted by one or more radicals R¹; two radicals R which are bonded to the same atom E may also form a mono- or polycyclic, aliphatic ring system with one another here. These radicals R are particularly preferably selected on each occurrence, identically or differently, from the group consisting of F, a straight-chain alkyl or alkoxy group having 1 to 6C atoms or a branched or cyclic alkyl or alkoxy group having 3 to 6C atoms, where one or more H atoms may be replaced by F, or an aromatic or heteroaromatic ring system having 5 to 24 aromatic ring atoms, which may in each case be substituted by one or more radicals R¹.

In a further preferred embodiment of the invention, the substituents R which are not bonded to E and do not stand for the radicals on the phosphorus or nitrogen if the coordinating group L¹ stands for PR₂ or NR₂ are selected on each occurrence, identically or differently, from the group consisting of H, D, F, Br, I, N(R¹)₂, CN, Si(R¹)₃, B(OR¹)₂, C(═O)R¹, a straight-chain alkyl group having 1 to 10C atoms or an alkenyl group having 2 to 10C atoms or a branched or cyclic alkyl group having 3 to 10C atoms, each of which may be substituted by one or more radicals R¹, where one or more H atoms may be replaced by D or F, or an aromatic or heteroaromatic ring system having 5 to 30 aromatic ring atoms, which may in each case be substituted by one or more radicals R¹; two adjacent radicals R may also form a mono- or polycyclic, aliphatic ring system with one another here. These radicals R are particularly preferably selected on each occurrence, identically or differently, from the group consisting of H, D, F, N(R¹)₂, a straight-chain alkyl group having 1 to 6C atoms or a branched or cyclic alkyl group having 3 to 10C atoms, where one or more H atoms may be replaced by D or F, or an aromatic or heteroaromatic ring system having 5 to 24 aromatic ring atoms, which may in each case be substituted by one or more radicals R¹; two adjacent radicals R may also form a mono- or polycyclic, aliphatic or aromatic ring system with one another here.

Preferred ligands L² are described below in the case of separate ligands. If the groups L² are bonded to L¹ and thus do not stand for a separate ligand, but instead for a coordinating group, the same preferences as described above for L¹ apply to L².

The ligands L² are neutral or monoanionic ligands, preferably neutral ligands, so that overall neutral complexes arise. They may be monodentate, or, if two ligands L² are bonded to one another, also bidentate, i.e. have two coordination sites.

Preferred neutral, monodentate ligands L² are selected from the group consisting of carbon monoxide, nitrogen monoxide, alkyl cyanides, such as, for example, acetonitrile, aryl cyanides, such as, for example, benzonitrile, alkyl isocyanides, such as, for example, methyl isonitrile, aryl isocyanides, such as, for example, benzoisonitrile, amines, such as, for example, trimethylamine, triethylamine, morpholine, phosphines, in particular halophosphines, trialkylphosphines, triarylphosphines or alkylarylphosphines, such as, for example, trifluorophosphine, trimethylphosphine, tricyclohexylphosphine, tri-tert-butylphosphine, triphenylphosphine, tris-(pentafluorophenyl)phosphine, dimethylphenylphosphine, methyldiphenylphosphine, bis(tert-butyl)phenylphosphine, phosphites, such as, for example, trimethyl phosphite, triethyl phosphite, arsines, such as, for example, trifluoroarsine, trimethylarsine, tricyclohexylarsine, tri-tert-butylarsine, tri-phenylarsine, tris(pentafluorophenyl)arsine, stibines, such as, for example, trifluorostibine, trimethylstibine, tricyclohexylstibine, tri-tert-butylstibine, tri-phenylstibine, tris(pentafluorophenyl)stibine, nitrogen-containing heterocycles, such as, for example, pyridine, pyridazine, pyrazine, pyrimidine, triazine, and carbenes, in particular Arduengo carbenes.

Preferred neutral, bidentate ligands, which are formed by two ligands L² bonding to one another, are selected from diamines, such as, for example, ethylenediamine, N,N,N′,N′-tetramethylethylenediamine, propylenediamine, N,N,N′,N′-tetramethylpropylenediamine, cis- or trans-diamino-cyclohexane, cis- or trans-N,N,N′,N′-tetramethyldiaminocyclohexane, imines, such as, for example, 2-[1-(phenylimino)ethyl]pyridine, 2-[1-(2-methylphenylimino)ethyl]pyridine, 2-[1-(2,6-diisopropylphenylimino)ethyl]-pyridine, 2-[1-(methylimino)ethyl]pyridine, 2-[1-(ethylimino)ethyl]pyridine, 2-[1-(isopropylimino)ethyl]pyridine, 2-[1-(tert-butylimino)ethyl]pyridine, diimines, such as, for example, 1,2-bis(methylimino)ethane, 1,2-bis(ethyl-imino)ethane, 1,2-bis(isopropylimino)ethane, 1,2-bis(tert-butylimino)ethane, 2,3-bis(methylimino)butane, 2,3-bis(ethylimino)butane, 2,3-bis(iso-propylimino)butane, 2,3-bis(tert-butylimino)butane, 1,2-bis(phenylimino)ethane, 1,2-bis(2-methylphenylimino)ethane, 1,2-bis(2,6-diisopropylphenyl-imino)ethane, 1,2-bis(2,6-di-tert-butylphenylimino)ethane, 2,3-bis(phenyl-imino)butane, 2,3-bis(2-methylphenylimino)butane, 2,3-bis(2,6-diisopropyl-phenylimino)butane, 2,3-bis(2,6-di-tert-butylphenylimino)butane, heterocycles containing two nitrogen atoms, such as, for example, 2,2′-bipyridine, o-phenanthroline, diphosphines, such as, for example, bis(diphenyl-phosphino)methane, bis(diphenylphosphino)ethane, bis(diphenyl-phosphino)propane, bis(diphenylphosphino)butane, bis(dimethylphosphino)methane, bis(dimethylphosphino)ethane, bis(dimethylphosphino)propane, bis(diethylphosphino)methane, bis(diethylphosphino)ethane, bis(diethylphosphino)propane, bis(di-tert-butylphosphino)methane, bis(di-tert-butylphosphino)ethane or bis(tert-butylphosphino)propane.

The ligand L² is particularly preferably a phosphine or, if two ligands L² are bonded to one another to form a bidentate ligand, a diphosphine.

The preferred embodiments indicated above can be combined with one another as desired. In a particularly preferred embodiment of the invention, the preferred embodiments indicated above apply simultaneously.

Examples of metal complexes according to the invention are the structures shown in the following table:

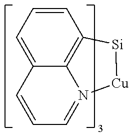

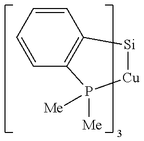

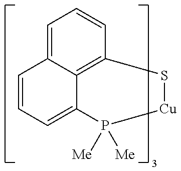

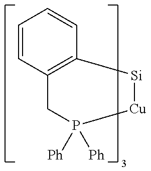

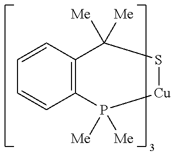

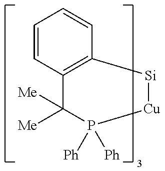

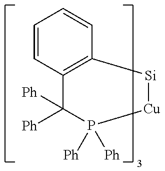

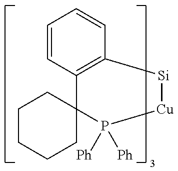

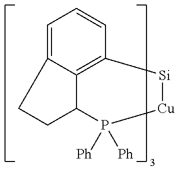

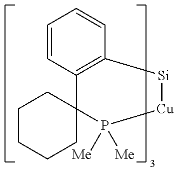

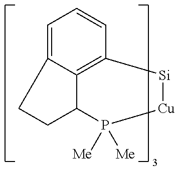

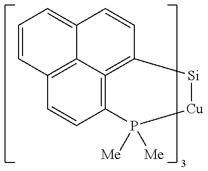

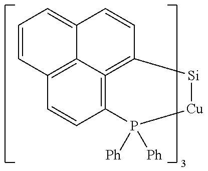

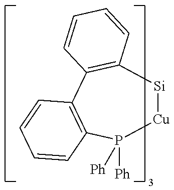

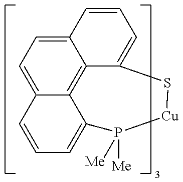

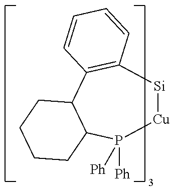

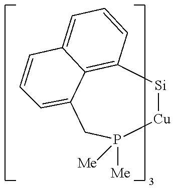

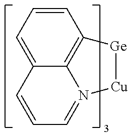

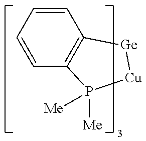

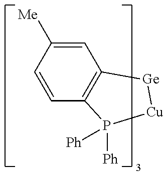

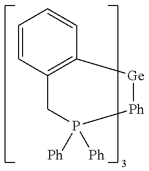

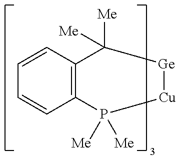

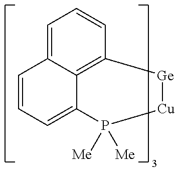

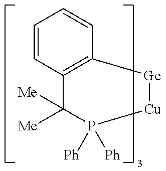

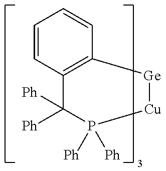

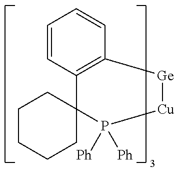

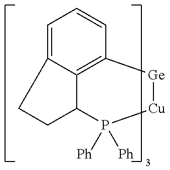

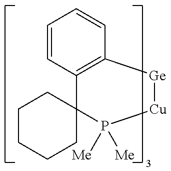

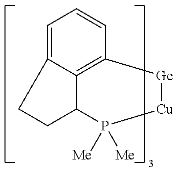

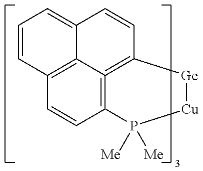

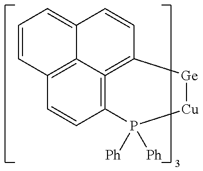

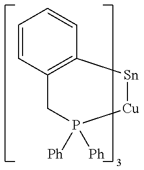

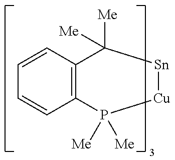

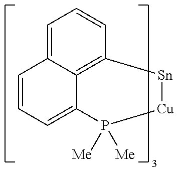

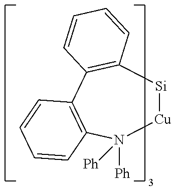

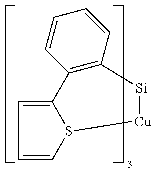

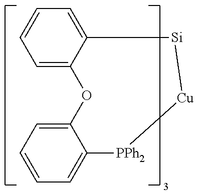

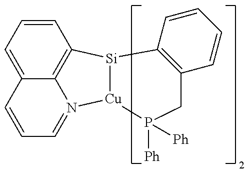

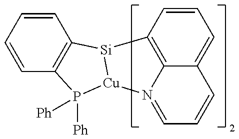

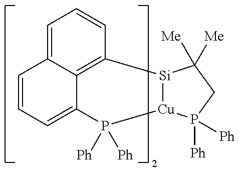

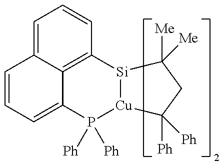

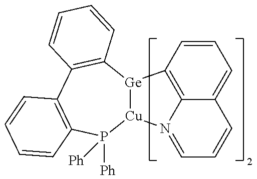

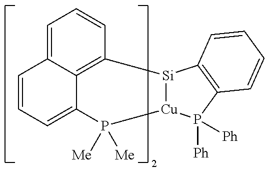

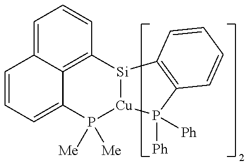

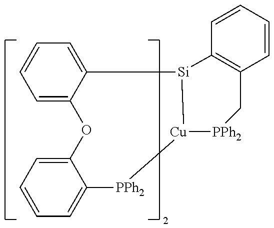

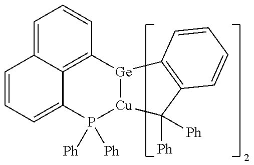

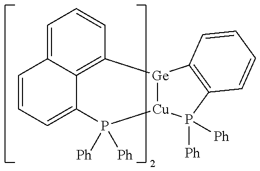

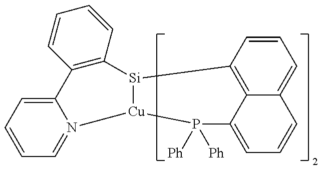

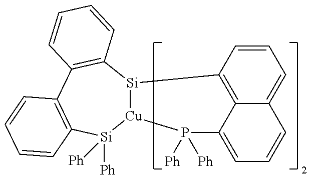

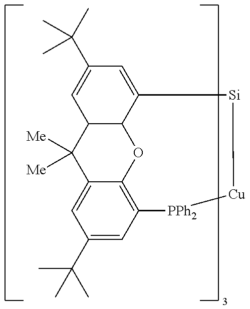

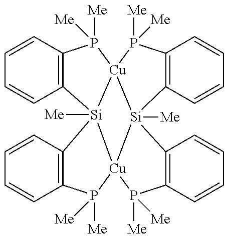

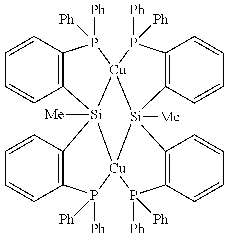

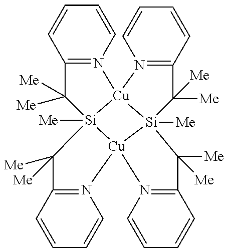

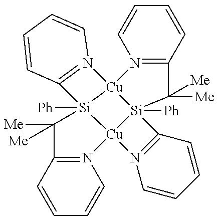

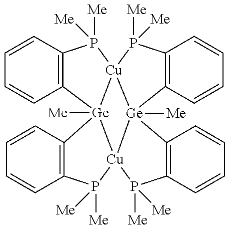

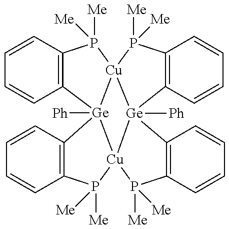

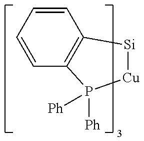

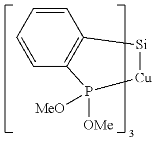

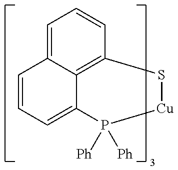

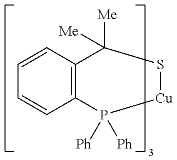

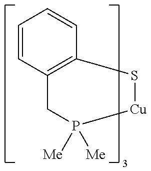

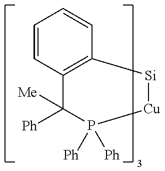

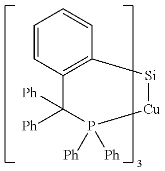

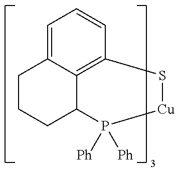

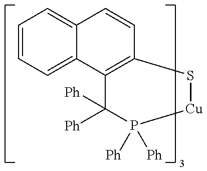

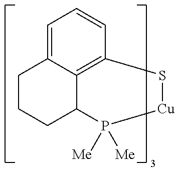

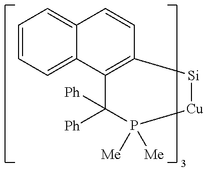

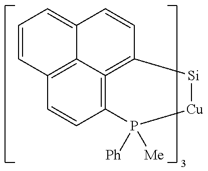

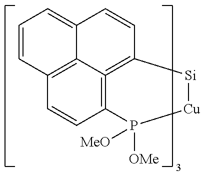

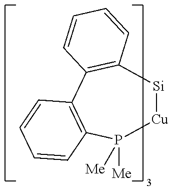

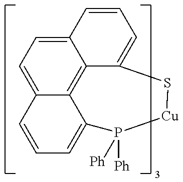

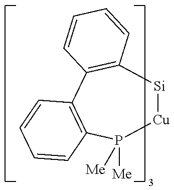

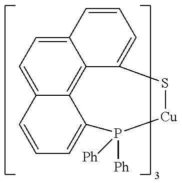

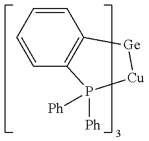

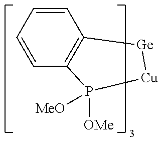

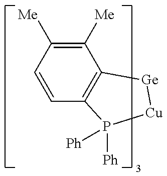

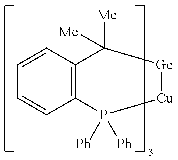

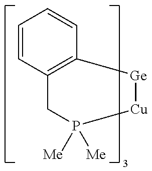

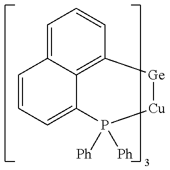

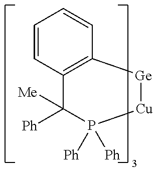

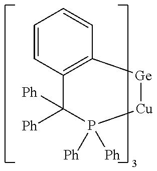

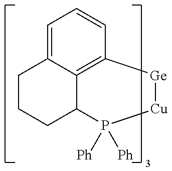

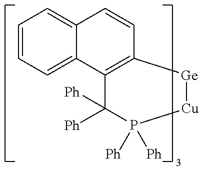

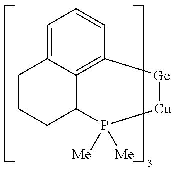

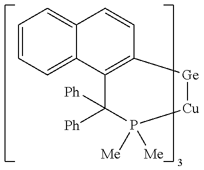

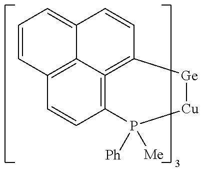

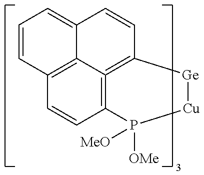

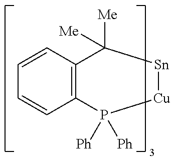

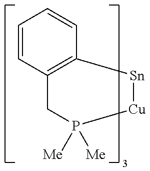

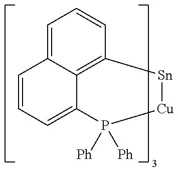

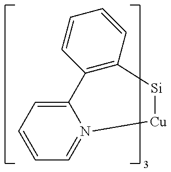

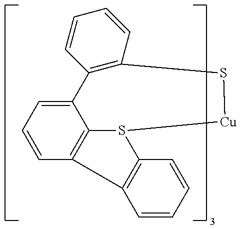

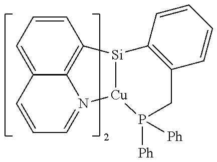

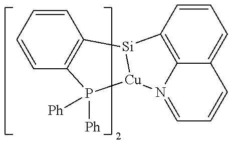

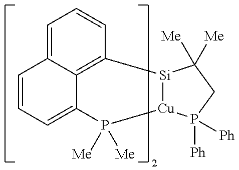

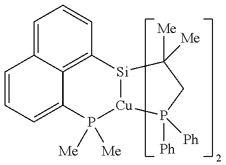

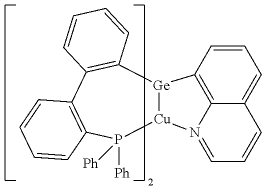

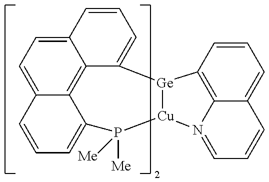

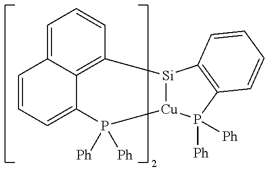

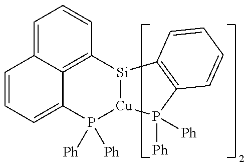

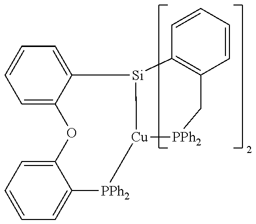

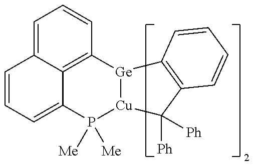

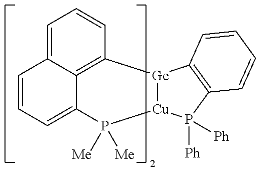

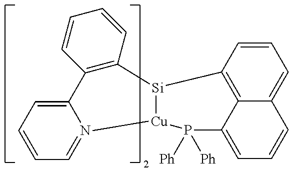

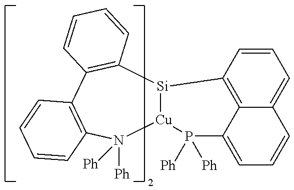

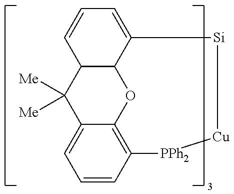

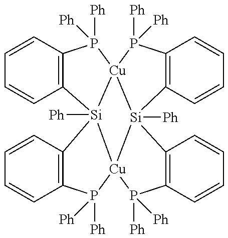

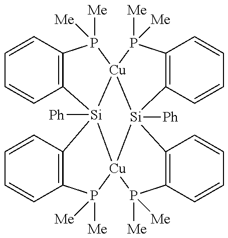

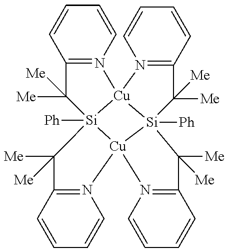

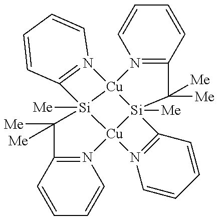

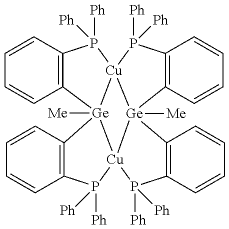

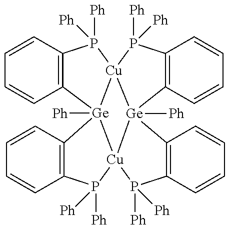

The present invention furthermore relates to a process for the preparation of the compounds of the formula (1), (2) or (3) by reaction of the corresponding free ligands which contain the groups E and L¹, optionally in deprotonated form, and optionally further ligands L² with suitable metal salts or metal complexes. The deprotonation reaction of the ligand can either be carried out in situ, for example if a metal salt having a basic anion is employed, or the corresponding anion is already prepared from the ligand before the reaction with the metal by deprotonation.

If the deprotonation of the ligand is to be carried out in situ, use is made, for example, of a metal complex having a basic ligand which, after its deprotonation, preferably has a less-nucleophilic character. Suitable copper starting materials are, for example, mesitylcopper, various copper amides, copper phosphides, copper alkoxides, copper acetate, etc. Suitable silver starting materials are, for example, mesitylsilver, various silver amides, silver phosphides, silver alkoxides, etc. Suitable gold starting materials are, for example, mesitylgold, various gold amides, gold phosphides, gold alkoxides, etc.

If the deprotonation of the ligand is to be carried out before the reaction with the metal M, use is preferably made of an alkali-metal salt having a basic anion which, after protonation, preferably has a less nucleophilic character and particularly preferably in protonated form is a volatile compound. This produces the corresponding alkalimetal salt of the ligand, which is then reacted with a metal salt (for example [Cu(MeCN)₄][BF₄]) to give the metal complex. Suitable salts for the deprotonation are, for example, sodium tert-butoxide, potassium tert-butoxide, lithium piperidide, bis(trimethylsilyl)amides (for example K[N(SiMe₃)₂]), etc.

The synthesis here can, for example, also be activated thermally, photochemically and/or by microwave radiation. The synthesis can likewise be carried out in an autoclave.

These processes, optionally followed by purification, such as, for example, recrystallisation, sublimation or, if necessary, chromatography, enable the compounds of the formula (1), (2) or (3) according to the invention to be obtained in high purity, preferably greater than 99% (determined by means of ¹H-NMR and/or HPLC).

The compounds according to the invention can also be rendered soluble by suitable substitution, for example by relatively long alkyl groups (about 4 to 20C atoms), in particular branched alkyl groups, or optionally substituted aryl groups, for example, xylyl, mesityl or branched terphenyl or quaterphenyl groups. Compounds of this type are then soluble in common organic solvents, such as, for example, toluene or xylene, at room temperature in sufficient concentration to be able to process the complexes from solution. These soluble compounds are particularly suitable for processing from solution, for example by printing processes.

Processing of the compounds according to the invention from the liquid phase, for example by spin coating or by printing processes, requires formulations of the compounds according to the invention. These formulations can be, for example, solutions, dispersions or emulsions. It may be preferred to use mixtures of two or more solvents for this purpose. Suitable and preferred solvents are, for example, toluene, anisole, o-, m- or p-xylene, methyl benzoate, mesitylene, tetralin, veratrol, THF, methyl-THF, THP, chlorobenzene, dioxane, phenoxytoluene, in particular 3-phenoxy-toluene, (−)-fenchone, 1,2,3,5-tetramethylbenzene, 1,2,4,5-tetramethyl-benzene, 1-methylnaphthalene, 2-methylbenzothiazole, 2-phenoxyethanol, 2-pyrrolidinone, 3-methylanisole, 4-methylanisole, 3,4-dimethylanisole, 3,5-dimethylanisole, acetophenone, α-terpineol, benzothiazole, butyl benzoate, cumene, cyclohexanol, cyclohexanone, cyclohexylbenzene, decalin, dodecylbenzene, ethyl benzoate, indane, methyl benzoate, NMP, p-cymene, phenetole, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol mono-butyl ether, tripropylene glycol dimethyl ether, tetraethylene glycol dimethyl ether, 2-isopropylnaphthalene, pentylbenzene, hexylbenzene, heptyl-benzene, octylbenzene, 1,1-bis(3,4-dimethylphenyl)ethane or mixtures of these solvents.

The present invention therefore furthermore relates to a formulation comprising at least one compound according to the invention and at least one further compound. The further compound may be, for example, a solvent, in particular one of the above-mentioned solvents or a mixture of these solvents. However, the further compound may also be a further organic or inorganic compound which is likewise employed in the electronic device, for example a matrix material. This further compound may also be polymeric.

The compounds of the formula (1), (2) and (3) according to the invention or the preferred embodiments indicated above are suitable for use in an electronic device or as catalyst or for the generation of singlet oxygen. The present invention thus furthermore relates to the use of the compounds according to the invention in an electronic device or as catalyst or for the generation of singlet oxygen.

The present invention still furthermore relates to an electronic device which comprises at least one compound according to the invention.

An electronic device is taken to mean a device which comprises an anode, a cathode and at least one layer, where this layer comprises at least one organic or organometallic compound. The electronic device according to the invention thus comprises an anode, a cathode and at least one layer which comprises at least one compound of the formula (1), (2) or (3) given above. Preferred electronic devices here are selected from the group consisting of organic electroluminescent devices (OLEDs, PLEDs), organic integrated circuits (O-ICs), organic field-effect transistors (O-FETs), organic thin-film transistors (O-TFTs), organic light-emitting transistors (O-LETs), organic solar cells (O-SCs), organic optical detectors, organic photoreceptors, organic field-quench devices (O-FQDs), light-emitting electrochemical cells (LECs) or organic laser diodes (O-lasers), comprising at least one compound of the formula (1), (2) or (3) given above in at least one layer. Particular preference is given to organic electroluminescent devices. Active components are generally the organic or inorganic materials which have been introduced between the anode and cathode, for example charge-injection, charge-transport or charge-blocking materials, but in particular emission materials and matrix materials. The compounds according to the invention exhibit particularly good properties as emission material in organic electroluminescent devices. Organic electroluminescent devices are therefore a preferred embodiment of the invention.

The organic electroluminescent device comprises a cathode, an anode and at least one emitting layer. Apart from these layers, it may also comprise further layers, for example in each case one or more hole-injection layers, hole-transport layers, hole-blocking layers, electron-transport layers, electron-injection layers, exciton-blocking layers, electron-blocking layers, charge-generation layers and/or organic or inorganic p/n junctions. Interlayers which have, for example, an exciton-blocking function and/or control the charge balance in the electroluminescent device may likewise be introduced between two emitting layers. However, it should be pointed out that each of these layers does not necessarily have to be present.

The organic electroluminescent device here may comprise one emitting layer or a plurality of emitting layers. If a plurality of emission layers are present, these preferably have in total a plurality of emission maxima between 380 nm and 750 nm, resulting overall in white emission, i.e. various emitting compounds which are able to fluoresce or phosphoresce are used in the emitting layers. Particular preference is given to three-layer systems, where the three layers exhibit blue, green and orange or red emission (for the basic structure see, for example, WO 2005/011013), or systems which have more than three emitting layers. It may also be a hybrid system, where one or more layers fluoresce and one or more other layers phosphoresce.

In a preferred embodiment of the invention, the organic electroluminescent device comprises the compound of the formula (1), (2) or (3) or the preferred embodiments indicated above as emitting compound in one or more emitting layers.

If the compound of the formula (1), (2) or (3) is employed as emitting compound in an emitting layer, it is preferably employed in combination with one or more matrix materials. The mixture comprising the compound of the formula (1), (2) or (3) and the matrix material comprises between 1 and 99% by vol., preferably between 2 and 90% by vol., particularly preferably between 3 and 40% by vol., especially between 5 and 15% by vol., of the compound of the formula (1), (2) or (3), based on the mixture as a whole comprising emitter and matrix material. Correspondingly, the mixture comprises between 99.9 and 1% by vol., preferably between 99 and 10% by vol., particularly preferably between 97 and 60% by vol., in particular between 95 and 85% by vol., of the matrix material, based on the mixture as a whole comprising emitter and matrix material.

The matrix material employed can in general be all materials which are known in the prior art for this purpose. The triplet level of the matrix material is preferably higher than the triplet level of the emitter.

Suitable matrix materials for the compounds according to the invention are ketones, phosphine oxides, sulfoxides and sulfones, for example in accordance with WO 2004/013080, WO 2004/093207, WO 2006/005627 or WO 2010/006680, triarylamines, carbazole derivatives, for example CBP (N,N-biscarbazolylbiphenyl), m-CBP or the carbazole derivatives disclosed in WO 2005/039246, US 2005/0069729, JP 2004/288381, EP 1205527, WO 2008/086851 or US 2009/0134784, indolocarbazole derivatives, for example in accordance with WO 2007/063754 or WO 2008/056746, indenocarbazole derivatives, for example in accordance with WO 2010/136109 or WO 2011/000455, azacarbazoles, for example in accordance with EP 1617710, EP 1617711, EP 1731584, JP 2005/347160, bipolar matrix materials, for example in accordance with WO 2007/137725, silanes, for example in accordance with WO 2005/111172, azaboroles or boronic esters, for example in accordance with WO 2006/117052, diazasilole derivatives, for example in accordance with WO 2010/054729, diaza-phosphole derivatives, for example in accordance with WO 2010/054730, triazine derivatives, for example in accordance with WO 2010/015306, WO 2007/063754 or WO 2008/056746, zinc complexes, for example in accordance with EP 652273 or WO 2009/062578, dibenzofuran derivatives, for example in accordance with WO 2009/148015, or bridged carbazole derivatives, for example in accordance with US 2009/0136779, WO 2010/050778, WO 2011/042107 or WO 2011/088877.

It may also be preferred to employ a plurality of different matrix materials as a mixture, in particular at least one electron-conducting matrix material and at least one hole-conducting matrix material or at least two electron-conducting matrix materials. A preferred combination is, for example, the use of an aromatic ketone, a triazine derivative or a phosphine oxide derivative with a triarylamine derivative or a carbazole derivative as mixed matrix for the metal complex according to the invention. Preference is like-wise given to the use of a mixture of a charge-transporting, i.e. a hole- or electron-transporting matrix material and an electrically inert matrix material which is not involved or not essentially involved in charge transport, as described, for example, in WO 2010/108579.

It is furthermore preferred to employ a mixture of two or more emitters together with a matrix. The emitter having the shorter-wave emission spectrum serves as co-matrix for the emitter having the longer-wave emission spectrum here.

The compounds according to the invention can also be employed in other functions in the electronic device, for example as matrix material for fluorescent or phosphorescent emitters, as hole-transport material in a hole-injection or -transport layer, as charge-generation material or as electron-blocking material.

The cathode preferably comprises metals having a low work function, metal alloys or multilayered structures comprising various metals, such as, for example, alkaline-earth metals, alkali metals, main-group metals or lanthanoids (for example Ca, Ba, Mg, Al, In, Mg, Yb, Sm, etc.). Also suitable are alloys comprising an alkali metal or alkaline-earth metal and silver, for example an alloy comprising magnesium and silver. In the case of multilayered structures, further metals which have a relatively high work function, such as, for example, Ag, may also be used in addition to the said metals, in which case combinations of the metals, such as, for example, Mg/Ag, Ca/Ag or Ba/Ag, are generally used. It may also be preferred to introduce a thin interlayer of a material having a high dielectric constant between a metallic cathode and the organic semiconductor. Suitable for this purpose are, for example, alkali metal or alkaline-earth metal fluorides, but also the corresponding oxides or carbonates (for example LiF, Li₂O, BaF₂, MgO, NaF, CsF, Cs₂CO₃, etc.). Organic alkali-metal complexes, for example Liq (lithium quinolinate), are likewise suitable for this purpose. The layer thickness of this layer is preferably between 0.5 and 5 nm.

The anode preferably comprises materials having a high work function. The anode preferably has a work function of greater than 4.5 eV vs. vacuum. Suitable for this purpose are on the one hand metals having a high redox potential, such as, for example, Ag, Pt or Au. On the other hand, metal/metal oxide electrodes (for example Al/Ni/NiOₓ, Al/PtOₓ) may also be preferred. For some applications, at least one of the electrodes must be transparent or partially transparent in order either to facilitate irradiation of the organic material (O-SCs) or the coupling-out of light (OLEDs/PLEDs, O-LASERs). Preferred anode materials here are conductive mixed metal oxides. Particular preference is given to indium tin oxide (ITO) or indium zinc oxide (IZO). Preference is furthermore given to conductive, doped organic materials, in particular conductive doped polymers, for example PEDOT, PANI or derivatives of these polymers.

All materials as are used in accordance with the prior art for the layers can generally be used in the further layers, and the person skilled in the art will be able to combine each of these materials with the materials according to the invention in an electronic device without inventive step.

The device is correspondingly structured (depending on the application), provided with contacts and finally hermetically sealed, since the lifetime of such devices is drastically shortened in the presence of water and/or air.

Preference is furthermore given to an organic electroluminescent device, characterised in that one or more layers are coated by means of a sublimation process, in which the materials are vapour-deposited in vacuum sublimation units at an initial pressure of usually less than 10⁻⁵ mbar, preferably less than 10⁻⁶ mbar. It is also possible for the initial pressure to be even lower or even higher, for example less than 10⁻⁷ mbar.

Preference is likewise given to an organic electroluminescent device, characterised in that one or more layers are coated by means of the OVPD (organic vapour phase deposition) process or with the aid of carrier-gas sublimation, in which the materials are applied at a pressure of between 10⁻⁵ mbar and 1 bar. A special case of this process is the OVJP (organic vapour jet printing) process, in which the materials are applied directly through a nozzle and thus structured (for example M. S. Arnold et al., Appl. Phys. Lett. 2008, 92, 053301).

Preference is furthermore given to an organic electroluminescent device, characterised in that one or more layers are produced from solution, such as, for example, by spin coating, or by means of any desired printing process, such as, for example, screen printing, flexographic printing, offset printing or nozzle printing, but particularly preferably LITI (light induced thermal imaging, thermal transfer printing) or ink-jet printing. Soluble compounds are necessary for this purpose, which are obtained, for example, through suitable substitution.

The organic electroluminescent device may also be produced as a hybrid system by applying one or more layers from solution and applying one or more other layers by vapour deposition. Thus, for example, it is possible to apply an emitting layer comprising a compound of the formula (1), (2) or (3) and a matrix material from solution and to apply a hole-blocking layer and/or an electron-transport layer on top by vacuum vapour deposition.

These processes are generally known to the person skilled in the art and can be applied by him without problems to organic electroluminescent devices comprising compounds of the formula (1), (2) or (3) or the preferred embodiments indicated above.

The electronic devices according to the invention, in particular organic electroluminescent devices, are distinguished over the prior art by the following surprising advantages:
1. The compounds according to the invention are very highly suitable for use in organic electroluminescent devices, in particular as emitting compounds.
2. Organic electroluminescent devices comprising compounds of the formula (1), (2) or (3) as emitting materials have a good lifetime.
3. Organic electroluminescent devices comprising compounds of the formula (1), (2) or (3) as emitting materials have good efficiency.
4. The compounds according to the invention can also be achieved, in particular, with copper, which enables the rare metals iridium and platinum to be omitted.
5. The compounds according to the invention in some cases have a broad emission band. They are therefore particularly suitable for the production of white-emitting OLEDs for lighting applications in order to cover a broad colour space.

The invention is explained in greater detail by the following examples, without wishing to restrict it thereby. The person skilled in the art will be able use the descriptions to produce further compounds according to the invention without inventive step and will thus be able to carry out the invention throughout the range claimed.

### EXAMPLES

The following syntheses are carried out, unless indicated otherwise, in dried solvents under a protective-gas atmosphere. The metal complexes are additionally handled with exclusion of light. The solvents and reagents can be purchased, for example, from Sigma-ALDRICH or ABCR.

### Example 1

### a) Tris[(diphenylphosphino)methylphenyl]silane (HSiPPP)

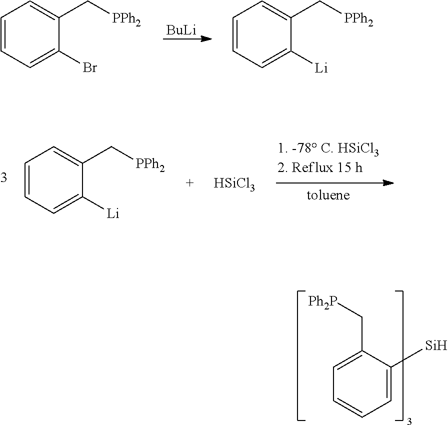

(o-Bromobenzyl)diphenylphosphine (3 g, 8.5 mmol) (H.-P. Abicht, K. Issleib, Z. Anorg. Allg. Chem. 1976, 422, 237-242) is dissolved in Et₂O (100 ml) and cooled to −78° C. n-Butyllithium (5.3 ml, 9.2 mmol, 1.6 M in hexane) is added dropwise to this solution. After 15 min., the solution is brought to room temperature and stirred for 2 h. The solvent is subsequently removed in a high vacuum. The residue is dissolved in toluene 50 ml and cooled to −35° C. The entire amount of trichlorosilane (383 mg, 2.8 mmol) is added to this solution in one portion. The apparatus is then sealed and warmed to room temperature. The reaction mixture is subsequently heated in the sealed apparatus at 90° C. for 15 h. After cooling, the solid formed is filtered off, and the solvent is distilled off in a high vacuum. The product is obtained as a colourless solid. Yield: 2.03 g (2.4 mmol), 85% of theory.

¹H NMR (400 MHz, CDCl₃): 6.91-7.53 (m, 30H, H—C_{Ph}), 3.56 (s, 6H, P—CH₂—C_{Ph}).

¹³C NMR (400 MHz, CDCl₃): 144.1, 137.9, 137.4, 133.3, 133.1, 132.7, 129.7, 129.6, 128.5, 128.2, 128.1, 125.6, 36.2(CH₂—P).

³¹P NMR (400 MHz, CDCl₃): −12.4.

### b) [Copper tris[(diphenylphosphino)methylphenyl]silanide]

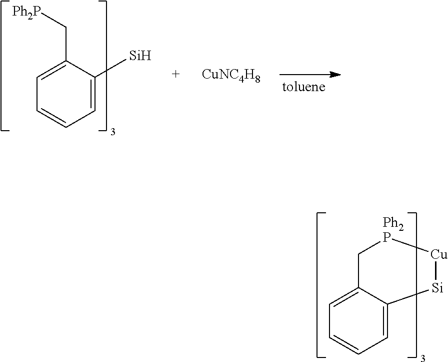

Copper pyrolidide (47 mg, 0.35 mmol) in toluene is added dropwise to a solution of HSiPPP (300 mg, 0.35 mmol) in toluene. The yellow-orange solution thus formed is stirred for 2 h, subsequently filtered and freed from solvent in a high vacuum. Red crystals are obtained by covering with a layer of toluene/hexane. Yield: 290 mg (0.31 mmol), 90% of theory.

¹H NMR (400 MHz, C₆D₆): 3.56 (br d, 6H, P—CH₂—C_{Ph}), 6.70-6.94 (30H, H—C_{Ph}), 7.08 (m, 3H, H—C_{Ph}), 7.26 (m, 3H, H—C_{Ph}), 7.34 (m, 3H, H—C_{Ph}), 8.11 (m, 3H, H—C_{Ph}).

³¹P NMR (400 MHz, C₆D₆): 14.42.

The complex exhibits weakly orange luminescence in the solid state at room temperature and intensely red luminescence at lower temperature.

### Example 2

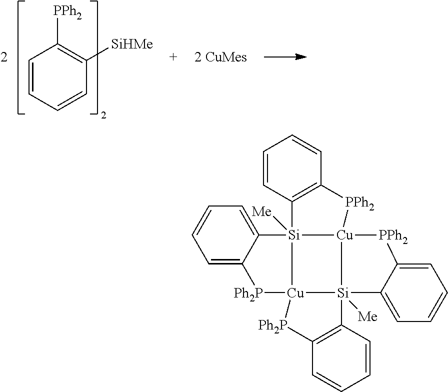

20 mg of CuMes (0.11 mmol) and 62 mg of (PSiP)H (0.11 mmol) (M. C. MacInnis, D. F. MacLean, R. J. Lundgren, R. McDonald, L. Turculet, Organometallics, 2007, 26, 6522-6525) are dissolved in 5 ml of toluene and filtered after 2 days. Orange crystals are obtained by slowly diffusing in n-hexane. Yield: 57 mg (0.045 mmol), 82% of theory.

¹H NMR (400 MHz, thf-d₈): 6.02-8.2 (56 H, all aromatic C—H),−0.33 (s, 6H, CH₃—Si).

³¹P {¹H} NMR (400 MHz, thf-d₈): 9.57(s), −7.21 (m)

Elemental analysis calculated for C₈₁H₇₀Cu₂P₄Si₂ (1350.60): C, 70.03; H, 5.22. Found: C, 71.80; H, 5.24.

### Example 3

### Synthesis of (Ph₂PXan)₃SiH

### a) Synthesis of “PPh₂XanBr”

The synthesis of the brominated xanthene derivative as starting material of step b) is carried out analogously to L. A. van der Veen, P. K. Keeven, P. C. J. Kamer, P. W. N. M. van Leeuwen, Chem. Commun. 2000, 333-334.

### b) Synthesis of (Ph₂PXan)₃SiH

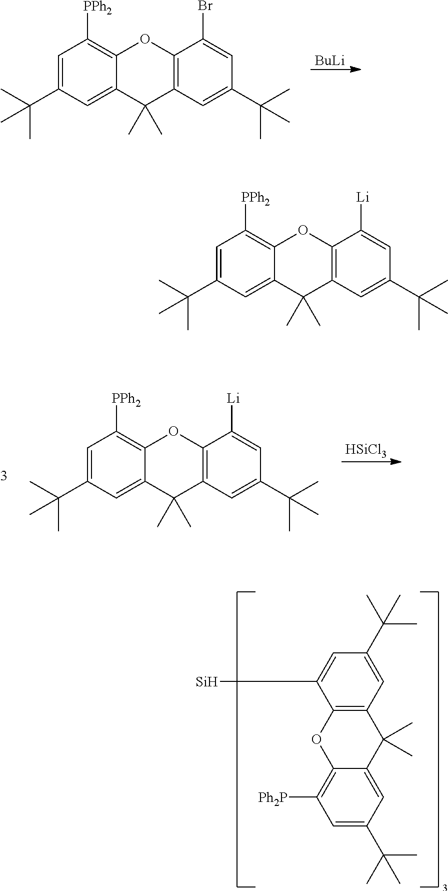

PPh₂XanBr (732.2 mg, 1.25 mmol, 3 eq.) are dissolved in 15 ml of diethyl ether and cooled to −78° C. 0.78 ml of a 1.6 molar n-butyllithium solution in hexane (1.25 mmol, 3 eq.) are then added dropwise very slowly. The solution changes colour to intense yellow. After stirring at −78° C. for 20 minutes, the mixture is warmed to room temperature and stirred for a further hour. The solvent is subsequently removed in vacuo, and the residue is taken up in 10 ml of toluene. The orange-coloured solution is cooled to −78° C., and trichlorosilane (56.4 mg, 0.417 mmol, 1 eq.) is added in one portion. The solution slowly becomes colourless during this addition. The vessel is sealed and firstly warmed to room temperature and subsequently heated at 90° C. for 17 h. During this time, the solution becomes completely colour-less, and a pale precipitate forms. The precipitate is filtered off, and the solid is rinsed twice with 3 ml of toluene each time. The toluene is removed from the toluene solutions in vacuo. A pale solid remains, which is recrystallised from hexane at −28° C.

¹H-NMR (C₆D₆): 1.13 (s, 27H, t-Bu), 1.23 (s, 27H, t-Bu), 1.84 (s, 9H, Me), 1.88 (s, 9H, Me), 6.88-6.95 (m, 9H), 6.96-7.00 (m, 3H), 7.09-7.22 (m, 21H), 7.59-7.64 (m, 9H) ppm.

³¹P-NMR (C₆D₆): −17.6 ppm.

²⁹Si-NMR (C₆D₆): −28.3 (q, 9.7 Hz) ppm.

Production of the OLEDs

1) Vacuum-Processed Devices:

OLEDs according to the invention and OLEDs in accordance with the prior art are produced by a general process in accordance with WO 2004/058911, which is adapted to the circumstances described here (layer-thickness variation, materials used).

The results for various OLEDs are presented in the following examples. Glass plates with structured ITO (indium tin oxide) form the substrates to which the OLEDs are applied. The OLEDs have in principle the following layer structure: substrate/hole-transport layer 1 (HTL1) consisting of HTM doped with 3% of NDP-9 (commercially available from Novaled), 20 nm/hole-transport layer 2 (HTL2)/optional electron-blocking layer (EBL)/emission layer (EML)/optional hole-blocking layer (HBL)/electron-transport layer (ETL)/optional electron-injection layer (EIL) and finally a cathode. The cathode is formed by an aluminium layer with a thickness of 100 nm

Firstly, vacuum-processed OLEDs are described. For this purpose, all materials are applied by thermal vapour deposition in a vacuum chamber. The emission layer here always consists of at least one matrix material (host material) and an emitting dopant (emitter), which is admixed with the matrix material or matrix materials in a certain proportion by volume by co-evaporation. An expression such as M3:M2:Ex. (55%:35%:10%) here means that material M3 is present in the layer in a proportion by volume of 55%, M2 is present in the layer in a proportion of 35% and the Cu emitter according to Ex. is present in the layer in a proportion of 10%. Analogously, the electron-transport layer may also consist of a mixture of two materials. The precise structure of the OLEDs is shown in Table 1. The materials used for the production of the OLEDs are shown in Table 4.

The OLEDs are characterised by standard methods. For this purpose, the electroluminescence spectra, the external quantum efficiency (in %) and the voltage (measured at 300 cd/m² in V) are determined from current/voltage/luminance characteristic lines (IUL characteristic lines).

Use of Compounds According to the Invention as Emitter Materials in Phosphorescent OLEDs

The compounds according to the invention can be employed, inter alia, as emitter materials in the emission layer in OLEDs.

TABLE 1
Structure of the OLED

| | HTL2 | EBL | EML | HBL | ETL |
|---|---|---|---|---|---|
| Ex. | Thickness | Thickness | Thickness | Thickness | Thickness |
| D- | HTM | — | M1:M3:Ex. 1 | — | ETM1:ETM2 |
| Ex. | 75 nm | | (35%:60%:5%) | | (50%:50%) |
| 1 | | | 30 nm | | 25 nm |
| D- | HTM | — | M2:M3:Ex. 2 | HBM | ETM1:ETM2 |
| Ex. | 75 nm | | (25%:70%:5%) | 10 nm | (50%:50%) |
| 2 | | | 30 nm | | 25 nm |

TABLE 2
Results of the vacuum-processed OLEDs

| | EQE (%) | Voltage (V) | CIE x/y |
|---|---|---|---|
| Ex. | 300 cd/m² | 300 cd/m² | 300 cd/m² |
| D-Ex. 1 | 6.1 | 4.8 | 0.63/0.36 |
| D-Ex. 2 | 10.2 | 4.4 | 0.48/0.51 |

2) Solution-Processed Devices:

A: From Soluble Functional Materials

The iridium complexes according to the invention can also be processed from solution, where they result in OLEDs which are significantly simpler as far as the process is concerned, compared with the vacuum-processed OLEDs, with nevertheless good properties. The production of components of this type is based on the production of polymeric light-emitting diodes (PLEDs), which has already been described many times in the literature (for example in WO 2004/037887). The structure is composed of substrate/ITO/PEDOT (80 nm)/interlayer (80 nm)/emission layer (80 nm)/cathode. To this end, use is made of substrates from Technoprint (soda-lime glass), to which the ITO structure (indium tin oxide, a transparent, conductive anode) is applied. The substrates are cleaned with DI water and a detergent (Deconex 15 PF) in a clean room and then activated by a UV/ozone plasma treatment. An 80 nm layer of PEDOT (PEDOT is a polythiophene derivative (Baytron P VAI 4083sp.) from H. C. Starck, Goslar, which is supplied as an aqueous dispersion) is then applied as buffer layer by spin coating, likewise in the clean room. The spin rate required depends on the degree of dilution and the specific spin coater geometry (typically for 80 nm:4500 rpm). In order to remove residual water from the layer, the substrates are dried by heating on a hotplate at 180° C. for 10 minutes. The interlayer used serves for hole injection, in this case HIL-012 from Merck is used. The interlayer may alternatively also be replaced by one or more layers, which merely have to satisfy the condition of not being detached again by the subsequent processing step of EML deposition from solution. In order to produce the emission layer, the emitters according to the invention are dissolved in toluene together with the matrix materials. The typical solids content of such solutions is between 16 and 25 g/l if, as here, the typical layer thickness of 80 nm for a device is to be achieved by means of spin coating. The solution-processed devices comprise an emission layer comprising (polystyrene):M5:M6:Ex. (25%:10%:55%:10%). The emission layer is applied by spin coating in an inert-gas atmosphere, in the present case argon, and dried by heating at 130° C. for 30 min. Finally, a cathode is applied by vapour deposition from barium (5 nm) and then aluminium (100 nm) (high-purity metals from Aldrich, particularly barium 99.99% (Order No. 474711); vapour-deposition equipment from Lesker, inter alia, typical vapour-deposition pressure 5×10⁻⁶ mbar). Optionally, firstly a hole-blocking layer and then an electron-transport layer and only then the cathode (for example Al or LiF/Al) can be applied by vacuum vapour deposition. In order to protect the device against air and atmospheric moisture, the device is finally encapsulated and then characterised. The OLED examples given have not yet been optimised, Table 3 summarises the data obtained.

TABLE 3
Results with materials processed from solution

| | | EQE (%) | Voltage (V) | CIE x/y |
|---|---|---|---|---|
| Ex. | Emitter Ex. | 300 cd/m² | 300 cd/m² | 300 cd/m² |
| D-Ex. 3 | Ex. 1 | 5.6 | 5.2 | 0.64/0.35 |
| D-Ex. 4 | Ex. 2 | 9.4 | 5.0 | 0.49/0.50 |

TABLE 4
Structural formulae of the materials used

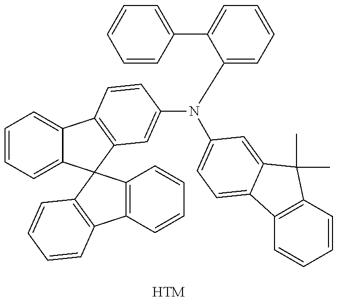

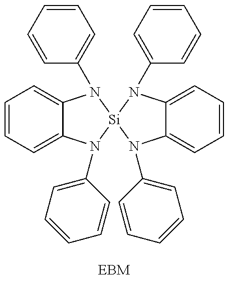 [SMILES: c1ccc(N2c3ccccc3N(c3ccccc3)[Si]23N(c2ccccc2)c2ccccc2N3c2ccccc2)cc1]

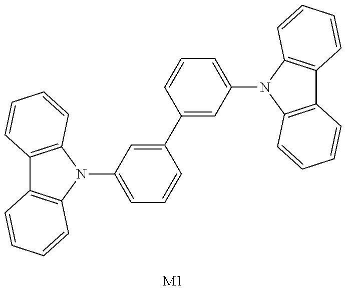 [SMILES: c1cc(-c2cccc(-n3c4ccccc4c4ccccc43)c2)cc(-n2c3ccccc3c3ccccc32)c1 ; "M1"]

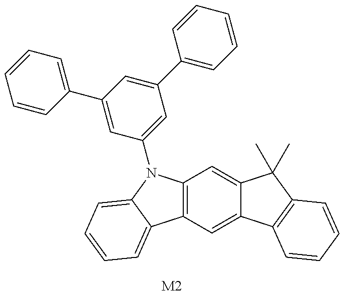

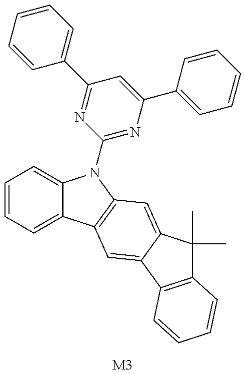 [SMILES: CC1(C)c2ccccc2-c2cc3c4ccccc4n(-c4nc(-c5ccccc5)cc(-c5ccccc5)n4)c3cc21 ; "M3"]

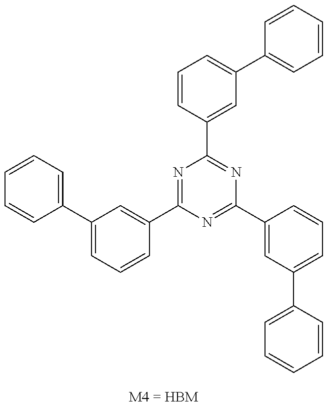 [SMILES: c1ccc(-c2cccc(-c3nc(-c4cccc(-c5ccccc5)c4)nc(-c4cccc(-c5ccccc5)c4)n3)c2)cc1]

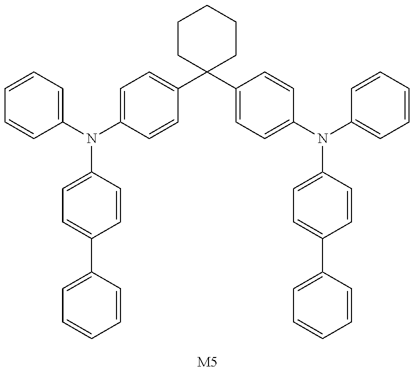 [SMILES: c1ccc(-c2ccc(N(c3ccccc3)c3ccc(C4(c5ccc(N(c6ccccc6)c6ccc(-c7ccccc7)cc6)cc5)CCCCC4)cc3)cc2)cc1 ; "M5"]

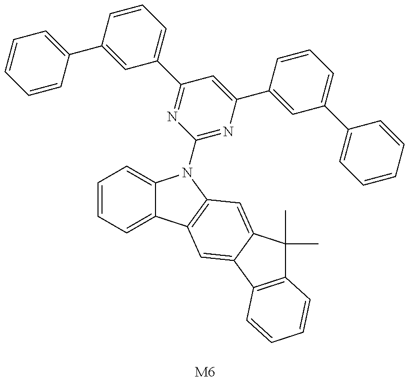 [SMILES: CC1(C)c2ccccc2-c2cc3c4ccccc4n(-c4nc(-c5cccc(-c6ccccc6)c5)cc(-c5cccc(-c6ccccc6)c5)n4)c3cc21 ; "M6"]

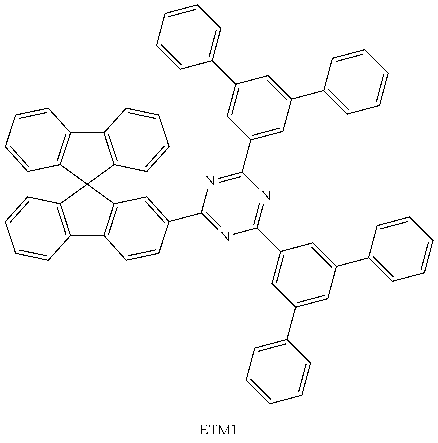 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1]

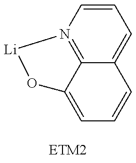

### DESCRIPTION OF THE FIGURES

FIG. 1: Crystal structure of the Cu complex from Example 1

FIG. 2: Crystal structure of the Cu complex from Example 2 (only one carbon atom of each of the phenyl groups is shown)

FIG. 3: Photoluminescence spectrum of the complex from Example 2 (a: solid spectrum, b: solution spectrum in toluene at room temperature)

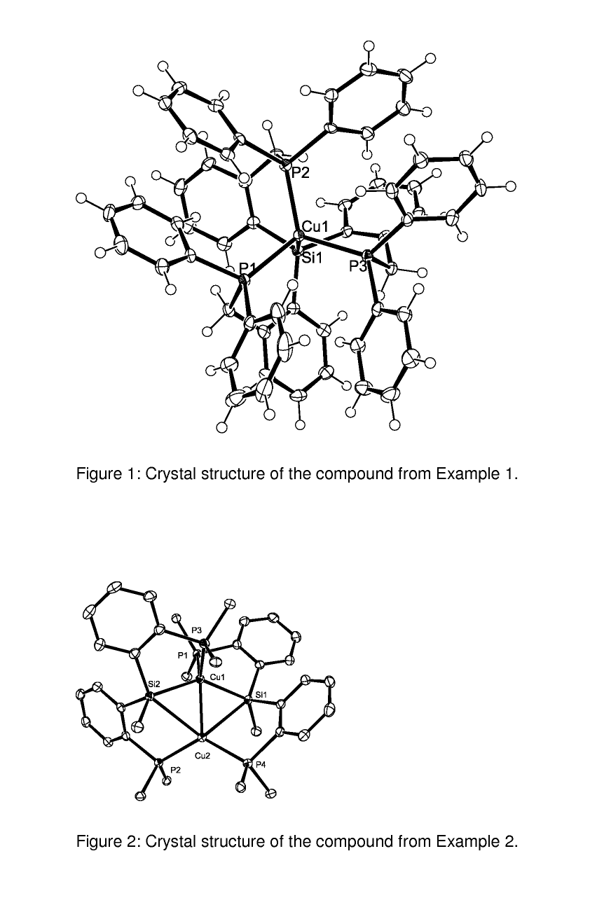

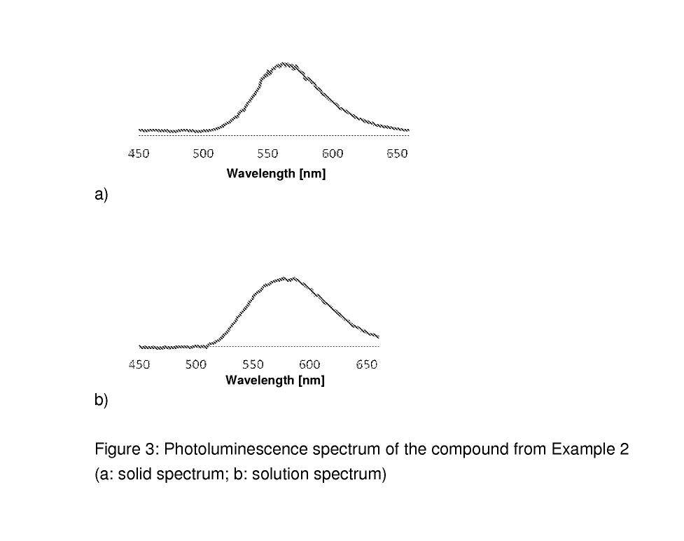

1-14. (canceled)

15. A compound of formula (1), (2), or (3): 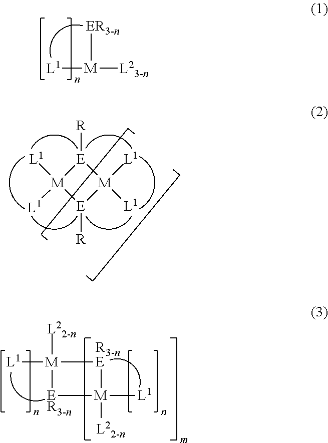
wherein
M is on each occurrence, identically or differently, Cu, Ag, or Au;
E is on each occurrence, identically or differently, Si, Ge, or Sn;
L¹ is on each occurrence, identically or differently, a coordinating group which is covalently bonded to E via a single bond or a bridging group, wherein two coordinating groups L¹ bonded to the same metal atom are optionally linked to one another via a single bond or a bridging unit;
L² is on each occurrence, identically or differently, a monodentate ligand which is coordinated to M, wherein two monodentate ligands L² coordinated to the same metal optionally together form a bidentate ligand, and wherein L² is optionally also linked to L¹ via a single bond or a bridging unit, wherein L² in this case is not an independent ligand, but instead a coordinating group;
R is on each occurrence, identically or differently, H, D, F, Cl, Br, I, N(R¹)₂, P(R¹)₂, CN, NO₂, OH, COOH, C(═O)N(R¹)₂, Si(R¹)₃, B(OR¹)₂, C(═O)R¹, P(═O)(R¹)₂, S(═O)R¹, S(═O)₂R¹, OSO₂R¹, a straight-chain alkyl, alkoxy, or thioalkoxy group having 1 to 20C atoms or an alkenyl or alkynyl group having 2 to 20C atoms or a branched or cyclic alkyl, alkoxy or thioalkoxy group having 3 to 20C atoms, each of which is optionally substituted by one or more radicals R¹, wherein one or more non-adjacent CH₂ groups are optionally replaced by R¹C═CR¹, C≡C, Si(R¹)₂, C═O, NR¹, O, S, or CONR¹, and wherein one or more H atoms are optionally replaced by D, F, Cl, Br, I, or CN, an aromatic or heteroaromatic ring system having 5 to 60 aromatic ring atoms optionally substituted by one or more radicals R¹, an aryloxy or heteroaryloxy group having 5 to 40 aromatic ring atoms optionally substituted by one or more radicals R¹, an aralkyl or hetero-aralkyl group having 5 to 40 aromatic ring atoms optionally substituted by one or more radicals R¹, or a diarylamino group, diheteroarylamino group, or arylheteroarylamino group having 10 to 40 aromatic ring atoms optionally substituted by one or more radicals R¹; and wherein two adjacent radicals R optionally define a mono- or polycyclic, aromatic or aliphatic ring system with one another;
R¹ is on each occurrence, identically or differently, H, D, F, Cl, Br, I, N(R²)₂, P(R²)₂, CN, NO₂, Si(R ²)₃, B(OR²)₂, C(═O)R², P(═O)(R²)₂, S(═O)R², S(═O)₂R², OSO₂R², a straight-chain alkyl, alkoxy, or thioalkoxy group having 1 to 20C atoms or an alkenyl or alkynyl group having 2 to 20C atoms or a branched or cyclic alkyl, alkoxy or thioalkoxy group having 3 to 20C atoms, each of which is optionally substituted by one or more radicals R², wherein one or more non-adjacent CH₂ groups are optionally replaced by R²C═CR², C≡C, Si(R²)₂, C═O, NR², O, S or CONR², and wherein one or more H atoms are optionally replaced by D, F, Cl, Br, I, CN, or NO₂, an aromatic or heteroaromatic ring system having 5 to 60 aromatic ring atoms optionally substituted by one or more radicals R², an aryloxy or heteroaryloxy group having 5 to 40 aromatic ring atoms optionally substituted by one or more radicals R², an aralkyl or heteroaralkyl group having 5 to 40 aromatic ring atoms optinoally substituted by one or more radicals R², or a diarylamino group, diheteroarylamino group, or arylheteroarylamino group having 10 to 40 aromatic ring atoms optionally substituted by one or more radicals R²; and wherein two or more adjacent radicals R² optionally define a mono- or polycyclic, aromatic, or aliphatic ring system with one another:
R² is on each occurrence, identically or differently, H, D, F, or an aliphatic, aromatic, and/or heteroaromatic hydrocarbon radical having 1 to 20C atoms, wherein one or more H atoms may be replaced by F; and wherein two or more substituents R² optionally define a mono- or polycyclic, aromatic or aliphatic ring system with one another;
n is 1, 2, or 3 in formula (1) or is 1 or 2 in formula (3);
m is 1, 2 or 3; and
wherein the curved line between L¹ and E is either a single bond by means of which L¹ is bonded to E, or a bridging unit by means of which L¹ is bonded to E.

16. The compound of claim 15, wherein M is Cu(I) and E is Si.

17. The compound of claim 15, wherein the compound of formula (1) is selected from the group consisting of the structures of formulae (1a), (1b), (1c), (1d), and (1e): 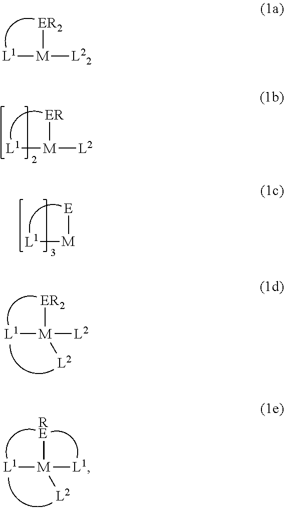
the compound of formula (2) is selected from the group consisting of the structures of formulae (2a), (2b), (2c): 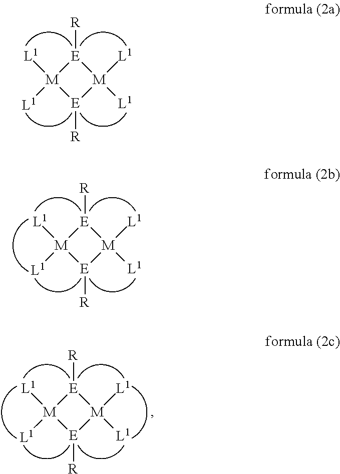
and the compound of formula (3) is selected from the group consisting of the structures of formulae (3a), (3b), and (3c): 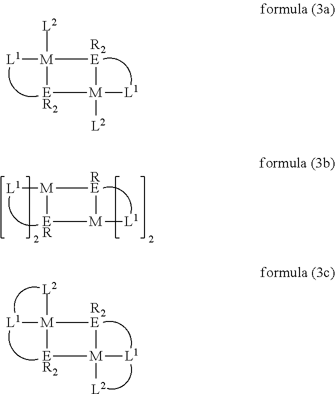
wherein the coordinating groups L¹ in formulae (2a) and (2b) are not bridged to one another if no bridging is drawn in.

18. The compound of claim 15, wherein the coordinating group L¹ is selected, identically or differently on each occurrence, from the group consisting of PR₂, NR₂, nitrogen-containing heteroaryl groups, which are coordinated to M via a neutral nitrogen atom, sulfur-containing heteroaryl groups, which are coordinated to M via the sulfur atom, SR, and —P═NR, wherein the nitrogen-containing or sulfur-containing heteroaryl groups are optionally substituted by one or more radicals R.

19. The compound of claim 15, wherein the coordinating group L¹, identically or differently on each occurrence, is
PR₂, wherein the radical R on the phosphorus is selected, identically or differently on each occurrence, from the group consisting of a straight-chain alkyl or alkoxy group having 1 to 10C atoms or a branched or cyclic alkyl or alkoxy group having 3 to 10C atoms, each of which is optionally substituted by one or more radicals R¹, wherein one or more non-adjacent CH₂ groups are optionally replaced by R¹C═CR¹ or O, and wherein one or more H atoms are optionally replaced by D or F, an aromatic or heteroaromatic ring system having 5 to 24 aromatic ring atoms optionally substituted by one or more radicals R¹, an aryloxy or heteroaryloxy group having 5 to 24 aromatic ring atoms optionally substituted by one or more radicals R¹, or an aralkyl or heteroaralkyl group having 5 to 40 aromatic ring atoms optionally substituted by one or more radicals R¹; and wherein two adjacent radicals R which are bonded to the same phosphorus atom optionally define a mono- or polycyclic, aromatic or aliphatic ring system with one another,
or
a nitrogen-containing heteroaryl group, which is coordinated to M via a neutral nitrogen atom and which in each case is optionally substituted by one or more radicals R.

20. The compound of claim 15, wherein L¹ is PR₂ or NR₂ and this group is bonded to E via a bridging group, wherein the bridging unit between the phosphorus or nitrogen atom and E is selected from the group consisting of an alkylene group having 1 to 3C atoms optionally substituted by one or more radicals R¹ and wherein one or more non-adjacent C atoms are also optionally replaced by —CR¹═CR¹— or O, an aromatic or heteroaromatic ring system having 5 to 18 aromatic ring atoms optionally substituted by one or more radicals R¹, or a combination of one or two alkylene groups, which are optionally substituted by one or more radicals R¹ and wherein one or more non-adjacent C atoms are optionally replaced by —CR¹═CR¹— or O, and an aromatic or heteroaromatic ring system.

21. The compound of claim 15, wherein the bridging unit, if L¹ is PR₂, NR₂, or —P═NR, is selected from the group consisting of the structures of formulae (4) to (23): 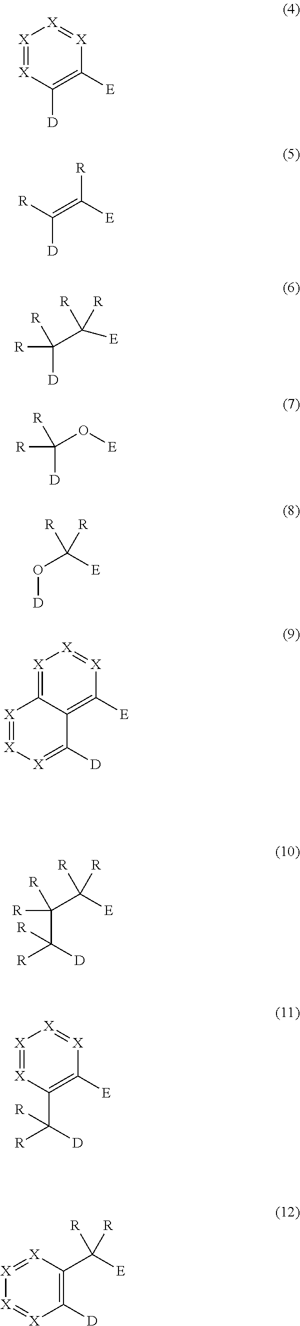 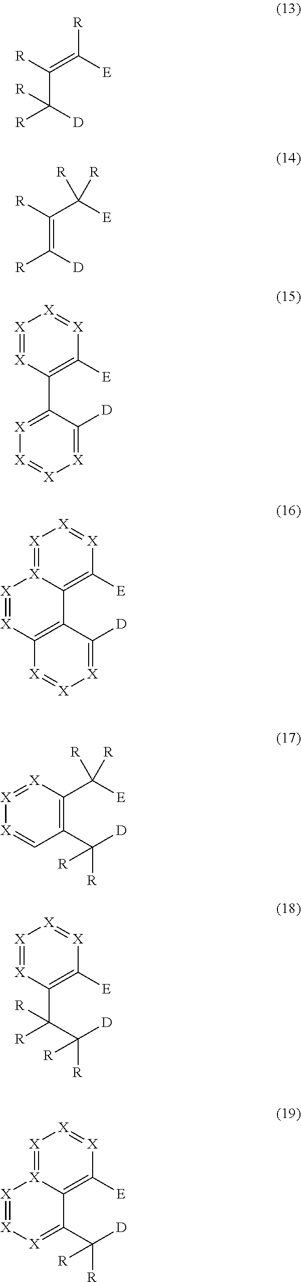 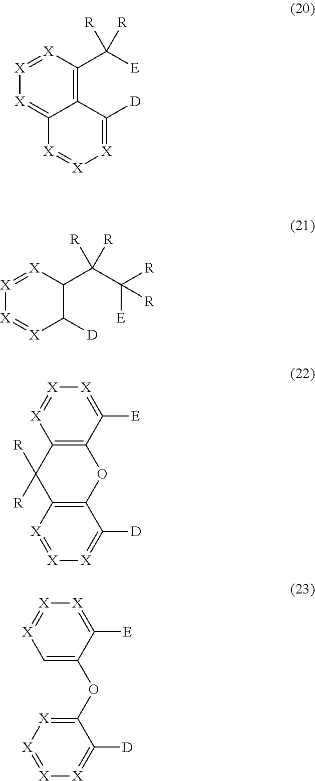
wherein the group E and the coordinating atom D of the coordinating group L¹ are in each case also drawn in in these structures and X is, identically or differently on each occurrence, CR or N, with the proviso that a maximum of three groups X per ring are N and the remaining groups X are CR;
or in that the coordinating group L¹ is a nitrogen-containing heteroaryl group and this group, together with the bridging group by means of which the heteroaryl group is bonded to E, is selected from the group consisting of the structures of formulae (24) to (29), 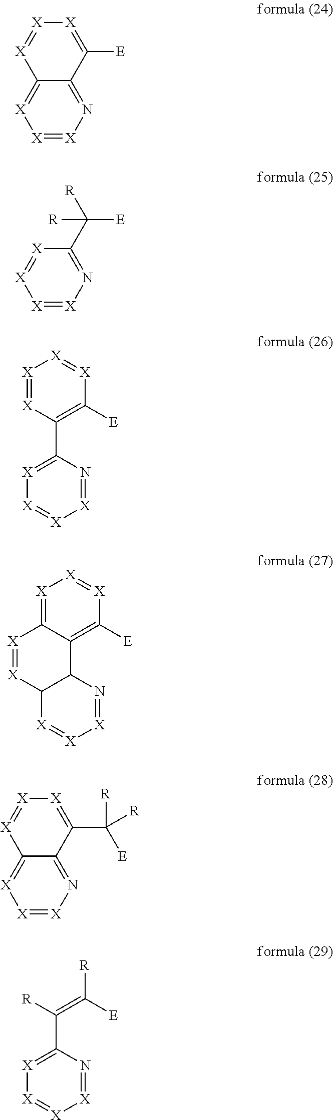
wherein the group E is also in each case drawn in in these structures and the nitrogen atom of the heteroaromatic group is coordinated to M;
or in that the coordinating group L¹ is a sulfur-containing heteroaryl group and this group, together with the bridging group by means of which the heteroaryl group is bonded to E, is selected from the group consisting of the structures of formulae (30) to (34): 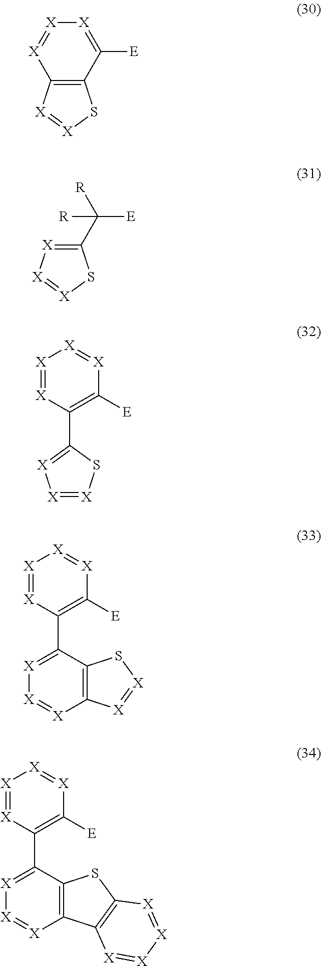
wherein the group E is in each case also drawn in in these structures and the nitrogen atom of the heteroaromatic group is coordinated to M.

22. The compound of claim 15, wherein the substituent R which is bonded to E is selected on each occurrence, identically or differently, from the group consisting of F, a straight-chain alkyl or alkoxy group having 1 to 10C atoms or an alkenyl group having 2 to 10C atoms or a branched or cyclic alkyl or alkoxy group having 3 to 10C atoms, each of which is optionally substituted by one or more radicals R¹, an aromatic or heteroaromatic ring system having 5 to 30 aromatic ring atoms optionally substituted by one or more radicals R¹; and wherein two radicals R bonded to the same atom E optionally define a mono- or polycyclic, aliphatic ring system with one another.

23. The compound of claim 15, wherein the monodentate ligand L² is selected from the group consisting of carbon monoxide, nitrogen monoxide, alkyl cyanides, aryl cyanides, alkyl isocyanides, aryl isocyanides, amines, phosphines, arsines, stibines, nitrogen-containing heterocycles, and nitrogen-containing carbenes, and wherein bidentate ligands formed by two ligands L² bonding to one another are selected from the group consisting of diamines, imines, heterocycles containing two nitrogen atoms, and diphosphines.

24. A process for preparing the compound of claim 15, comprising reacting free ligands, optionally in deprotonated form, and optionally further ligands L², with metal salts or metal complexes.

25. A formulation comprising at least one compound of claim 15 and at least one further compound.

26. The formulation of claim 25, wherein the formulation is a solution or dispersion.

27. The formulation of claim 25, wherein the at least one further compound is a solvent.

28. An electronic device comprising at least one compound of claim 15.

29. The electronic device, wherein the electronic device is selected from the group consisting of organic electroluminescent devices, organic integrated circuits, organic field-effect transistors, organic thin-film transistors, organic light-emitting transistors, organic solar cells, organic optical detectors, organic photoreceptors, organic field-quench devices, light-emitting electrochemical cells, and organic laser diodes.

30. The electronic device of claim 28, wherein the electronic device is an organic electroluminescent device and the compound of claim 15 is employed as an emitting compound in one or more emitting layers.
